(19) United States
(12) Patent Application Publication
(10) Pub. No.: US 2025/0072239 A1
(43) Pub. Date: Feb. 27, 2025

(54) DISPLAY DEVICE

(71) Applicant: SAMSUNG DISPLAY CO., LTD., YONGIN-SI (KR)

(72) Inventor: SANGHYUN LIM, Yongin-si (KR)

(21) Appl. No.: 18/739,513

(22) Filed: Jun. 11, 2024

(30) Foreign Application Priority Data
Aug. 25, 2023 (KR) 10-2023-0111996

(51) Int. Cl. H10K 59/131; H10K 59/80

(52) U.S. Cl. CPC H10K 59/131; H10K 59/873

(57) ABSTRACT

A display device includes a display panel including pixels, an encapsulation layer overlapping the pixels, and a dam; and an input sensing panel disposed on the display panel, wherein the input sensing panel includes an active area, a trace area adjacent to the active area, and a ground area spaced apart from the active area with the trace area interposed therebetween, sensing electrodes disposed in the active area, trace lines disposed in the trace area and connected to the sensing electrodes, and a ground pattern disposed in the trace area and the ground area, wherein the dam overlaps the ground area, and the ground pattern overlaps the dam.

### CROSS-REFERENCE TO RELATED APPLICATION

This U.S. non-provisional patent application claims priority under 35 U.S.C. § 119 to Korean Patent Application No. 10-2023-0111996, filed on Aug. 25, 2023, in the Korean Intellectual Property Office, the disclosure of which is incorporated by reference herein in its entirety.

### 1. TECHNICAL FIELD

The present disclosure relates to a display device. More particularly, the present disclosure relates to an input sensing panel of the display device.

### 2. DESCRIPTION OF THE RELATED ART

A display device is applied to various electronic devices, such as smartphones, televisions, computers, etc. The display device may include an input sensing panel to sense a user input applied thereto.

Electromagnetic signals create noise within the display device. This phenomenon is referred to as electromagnetic interference (EMI), and a technology to reduce the electromagnetic interference in the display device is in demand.

### SUMMARY

The present disclosure provides a display device including an input sensing panel capable of reducing electromagnetic interference.

Embodiments of the inventive concept provide a display device including a display panel comprising pixels, an encapsulation layer overlapping the pixels, and a dam; and an input sensing panel disposed on the display panel, wherein the input sensing panel comprises an active area, a trace area adjacent to the active area, and a ground area spaced apart from the active area with the trace area interposed therebetween, sensing electrodes disposed in the active area, trace lines disposed in the trace area and connected to the sensing electrodes, and a ground pattern disposed in the trace area and the ground area, wherein the dam overlaps the ground area, and the ground pattern overlaps the dam.

### BRIEF DESCRIPTION OF THE DRAWINGS

The above and other features of the present disclosure will become readily apparent by reference to the following detailed description when considered in conjunction with the accompanying drawings wherein:

FIG. 1 is a perspective view of a display device according to an embodiment of the present disclosure;

FIG. 2 is a cross-sectional view of a portion of a display device taken along a line I-I′ of FIG. 1;

FIG. 3 is a cross-sectional view of a display device according to an embodiment of the present disclosure;

FIG. 4 is a plan view of a display panel according to an embodiment of the present disclosure;

FIG. 5 is a cross-sectional view of a portion of a display device according to an embodiment of the present disclosure;

FIG. 6A is a plan view of an input sensing panel according to an embodiment of the present disclosure;

FIG. 6B is an enlarged plan view of an area TT′ of FIG. 6A;

FIG. 6C is a cross-sectional view of an input sensing panel taken along a line III-III′ of FIG. 6B;

FIG. 7 is a cross-sectional view of a portion of a display device taken along a line II-II′ of FIG. 6A;

FIG. 8A is a plan view of an input sensing panel according to an embodiment of the present disclosure;

FIG. 8B is a plan view of an input sensing panel according to an embodiment of the present disclosure;

FIG. 8C is a plan view of an input sensing panel according to an embodiment of the present disclosure;

FIG. 8D is a plan view of an input sensing panel according to an embodiment of the present disclosure;

FIG. 8E is a plan view of an input sensing panel according to an embodiment of the present disclosure;

FIG. 8F is a plan view of an input sensing panel according to an embodiment of the present disclosure;

FIG. 9A is a cross-sectional view of a display device according to an embodiment of the present disclosure;

FIG. 9B is a cross-sectional view of a display device according to an embodiment of the present disclosure;

FIG. 9C is a cross-sectional view of a display device according to an embodiment of the present disclosure;

FIG. 10A is a cross-sectional view of a display device according to an embodiment of the present disclosure;

FIG. 10B is a cross-sectional view of a display device according to an embodiment of the present disclosure;

FIG. 10C is a cross-sectional view of a display device according to an embodiment of the present disclosure;

FIG. 11A is a graph illustrating an electric capacitance of a display device according to an embodiment of the present disclosure and a display device according to a comparative example; and

FIG. 11B is a graph illustrating an electromagnetic interference field strength of a display device according to an embodiment of the present disclosure and a display device according to a comparative example.

### DETAILED DESCRIPTION OF THE EMBODIMENTS

The present disclosure may be modified and realized in many different forms, and thus specific embodiments will be illustrated in the drawings and described in detail hereinbelow. However, the present disclosure should not be necessarily limited to the specific disclosed forms, and should be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present. In the present disclosure, the expression “A component A is disposed directly on a component B” means that no intervening elements are present between the component A and the component B.

Like numerals may refer to like elements throughout the specification. In the drawings, the thickness, ratio, and dimension of components may be exaggerated for effective description of the technical content. As used herein, the term “and/or” may include any and all combinations of one or more of the associated listed items.

It will be understood that, although the terms first, second, etc. may be used herein to describe various elements, these elements should not be necessarily limited by these terms. These terms are used to distinguish one element from another element. Thus, a first element discussed below could be termed a second element. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

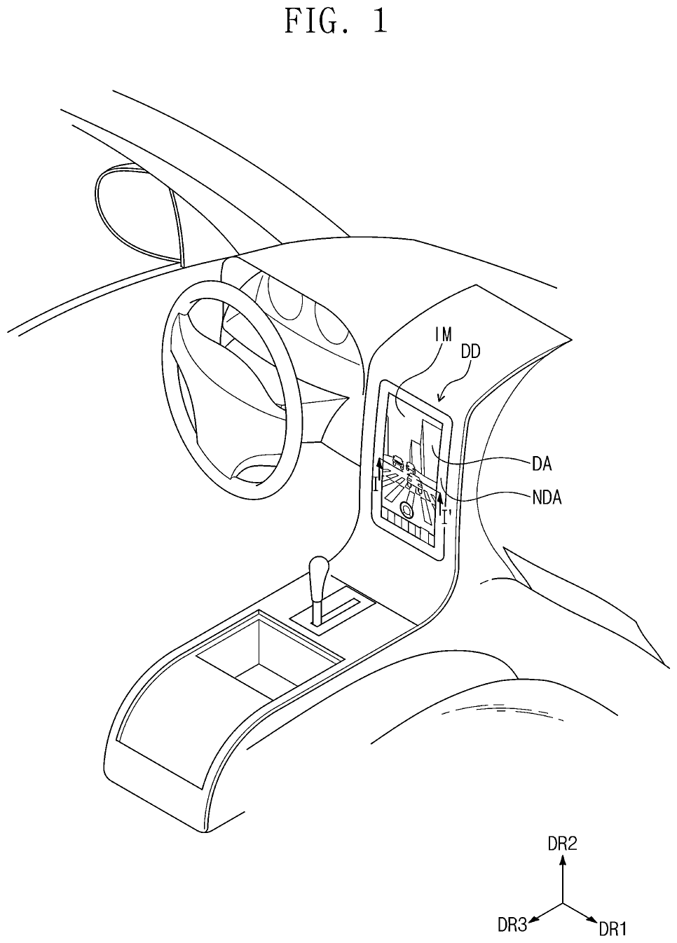

FIG. 1 is a perspective view of a display device DD according to an embodiment of the present disclosure.

The display device DD may be activated in response to electrical signals. The display device DD shown in FIG. 1 may be a center information display (CID) for a vehicle. The display device DD may be placed in the vehicle and may provide various information to a user, however, the present disclosure should not be necessarily limited thereto. For example, the display device DD may be applied to various embodiments, such as smartphones, tablet computers, televisions, digital cameras, etc.

The display device DD may be a touch display that responds to a user touch input.

The display device DD may include a display area DA and a non-display area NDA.

The image IM may be displayed through the display area DA. The display area DA may be parallel to a plane defined by a first direction DR1 and a second direction DR2 intersecting the first direction DR1. FIG. 1 shows a traffic situation as an example of the image IM; however, the present disclosure is not necessarily limited thereto. The image IM might not be displayed through the non-display area NDA. The non-display area NDA may be adjacent to the display area DA. For example, the non-display area NDA may at least partially surround the display area DA.

In the present embodiment, a third direction DR3 may be substantially perpendicular to a plane defined by the first direction DR1 and the second direction DR2. In the present disclosure, the expression “when viewed in a plane” may mean a state of being viewed in the third direction DR3.

In the following descriptions, upper (or front) and lower (or rear) surfaces of each member may be defined with respect to a direction in which the image IM is displayed. The upper and lower surfaces may face each other in the second direction DR2, and a normal line direction of each of the upper and lower surfaces may be substantially parallel to the third direction DR3. For example, directions indicated by the first, second, and third directions DR1, DR2, and DR3 may be relative to each other and may be interchangeable.

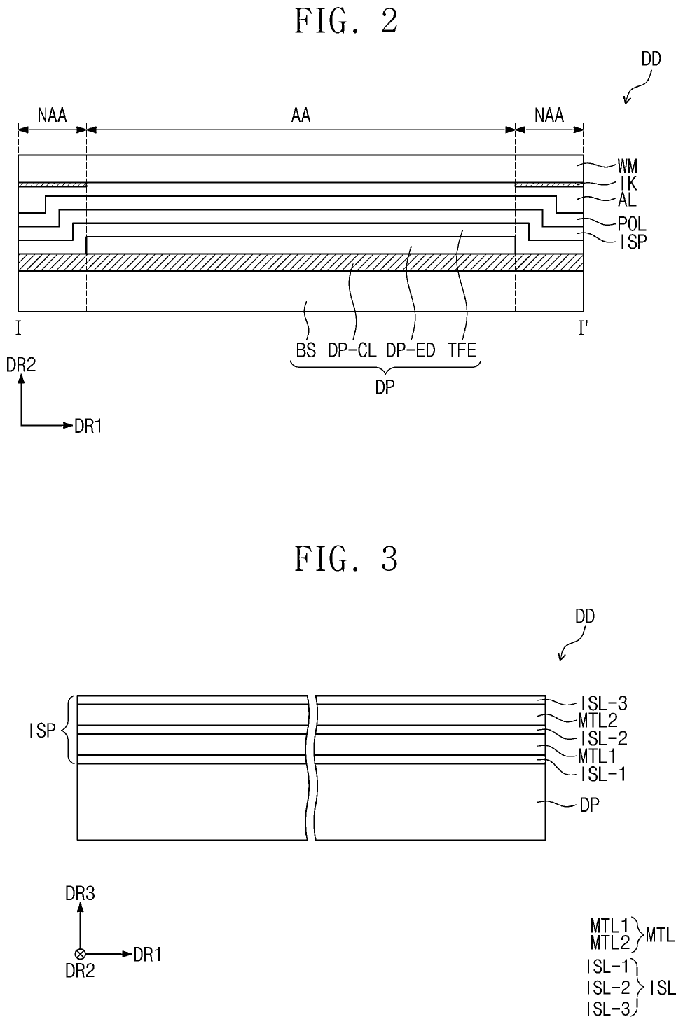

FIG. 2 is a cross-sectional view of a portion of the display device DD according to an embodiment of the present disclosure taken along a line I-I′ of FIG. 1.

The display device DD may include a display panel DP and an input sensing panel ISP disposed on the display panel DP.

The display panel DP may include a base layer BS, a circuit element layer DP-CL, a display element layer DP-ED, and an encapsulation layer TFE. The display panel DP may include configurations to generate the image IM (refer to FIG. 1). The display panel DP may be a light emitting type display panel, however, it should not be necessarily limited thereto. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The circuit element layer DP-CL may be disposed on the base layer BS and the display element layer DP-ED may be disposed on the circuit element layer DP-CL. The encapsulation layer TFE may be disposed on the display element layer DP-ED. For example, the circuit element DP-CL may be disposed between the base layer BS and the display element layer DP-ED. Components included in the display panel DP will be described in detail with reference to FIG. 3.

The input sensing panel ISP may be disposed on the display panel DP. The input sensing panel ISP may sense an external input applied from the outside. The external input may include a variety of inputs provided from the outside of the display device DD. For example, the external inputs may include a proximity input (e.g., hovering) applied when approaching close to or adjacent to the display device DD at a predetermined distance, or a touch input by a part of the user's body (e.g., the user's hand). The external inputs may be provided in the form of force, pressure, light, etc.

The input sensing panel ISP may be formed on the display panel DP through successive processes. For example, the input sensing panel ISP may be disposed directly on the display panel DP. For example, no adhesive layer is disposed between the input sensing panel ISP and the display panel DP.

An optical layer POL may be disposed on the input sensing panel ISP. The optical layer POL may reduce a reflectance of the display panel DP with respect to the external light applied to the display panel DP. As an example, the optical layer POL may include at least one of an anti-reflective film, a polarization film, and a gray filter.

The cover window WM may be disposed on the optical layer POL. The cover window WM may protect the display panel DP from external impacts and may transmit images provided from the display panel DP to the outside. The cover window WM may include an optically transparent insulating material such as a glass or plastic material. The cover window WM may have a single-layer or multi-layer structure. As an example, the cover window WM may include a plurality of plastic films coupled with each other by an adhesive or may include a glass substrate and a plastic film coupled with the glass substrate by an adhesive.

An adhesive layer AL may be disposed between the cover window WM and the optical layer POL. The cover window WM may be coupled with the optical layer POL by the adhesive layer AL. The adhesive layer AL may include a pressure sensitive adhesive (PSA); however, it is not necessarily limited thereto. The adhesive included in the adhesive layer AL is optically transparent. The display device DD may further include an adhesive layer AL disposed between the input sensing panel ISP and the optical layer POL that attaches the input sensing panel ISP to the optical layer POL.

A light blocking pattern IK may be disposed on a lower surface of the cover window WM. The light blocking pattern IK may be a color layer and may prevent users from viewing the wirings of the display panel DP. The light blocking pattern IK may include a material with a color.

FIG. 3 is a cross-sectional view of the display device DD according to an embodiment of the present disclosure.

The display device DD may include the display panel DP and the input sensing panel ISP. The input sensing panel ISP may be referred to as a sensor layer, an input sensing layer, or an input sensing panel.

Referring to FIG. 3, the input sensing panel ISP may include a sensing insulating layer ISL and a conductive layer MTL. The sensing insulating layer ISL may include a first sensing insulating layer ISL-1, a second sensing insulating layer ISL-2, and a third sensing insulating layer ISL-3. The conductive layer MTL may include a first conductive layer MTL1 and a second conductive layer MTL2. However, the present disclosure is not necessarily limited thereto. For example, the first sensing insulating layer ISL-1 may be omitted.

According to an embodiment, the first sensing insulating layer ISL-1, the first conductive layer MTL1, the second sensing insulating layer ISL-2, the second conductive layer MTL2, and the third sensing insulating layer ISL-3, which are included in the input sensing panel ISP, may be sequentially stacked on the display panel DP along the third direction DR3.

Each of the first conductive layer MTL1 and the second conductive layer MTL2 may have a single-layer structure or a multi-layer structure. The conductive layer having the multi-layer structure may include two or more layers of a transparent conductive layer and/or a metal layer. As an example, the conductive layer having the multi-layer structure may include the transparent conductive layer and the metal layer or metal layers containing different metals from each other.

FIG. 3 shows each of the first conductive layer MTL1 and the second conductive layer MTL2 as a single layer that entirely overlaps the display panel DP to schematically represent the stacked structure. However, the present disclosure is not necessarily limited thereto. According to an embodiment, each of the first conductive layer MTL1 and the second conductive layer MTL2 may be patterned.

The first and second conductive layers MTL1 and MTL2 may be a transparent conductive layer and may include at least one of indium tin oxide (ITO), indium zinc oxide (IZO), zinc oxide (ZnO), indium tin zinc oxide (ITZO), PEDOT, metal nanowire, and graphene. The first and second conductive layers MTL1 and MTL2 may be the metal layer and may include molybdenum, silver, titanium, copper, aluminum, and/or alloys thereof.

Among the first and second conductive layers MTL1 and MTL2, metals with a relatively high durability and a low reflectance may be applied as an outer layer of the conductive layer, and metals with a high electrical conductivity may be applied as an inner layer of the conductive layer. As an example, each of the first and second conductive layers MTL1 and MTL2 may have a three-layer structure including titanium, aluminum, and titanium.

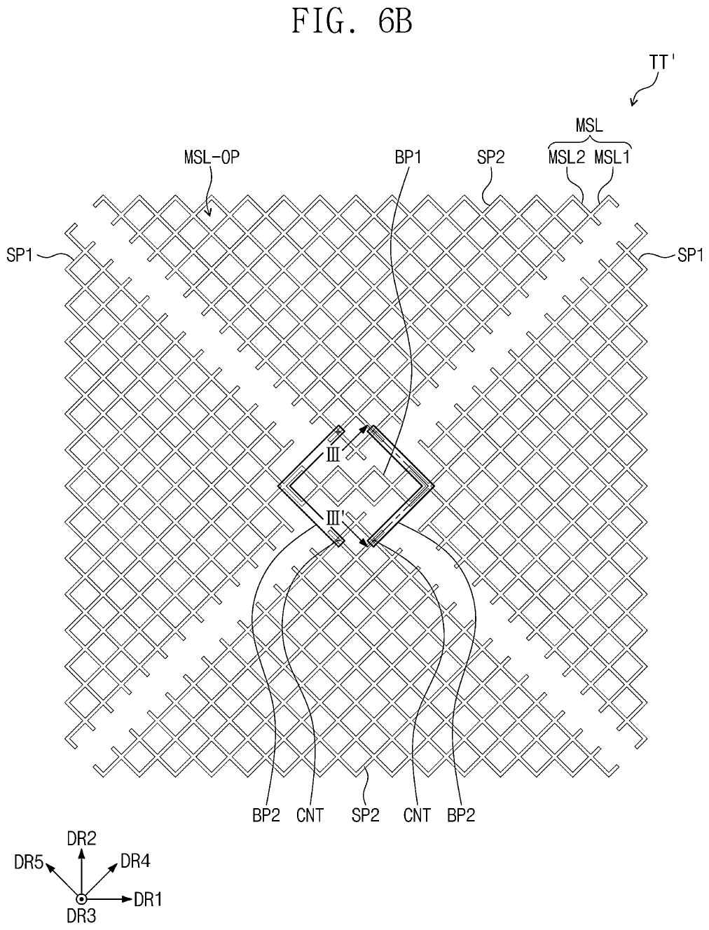

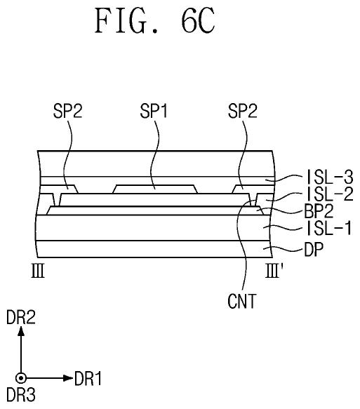

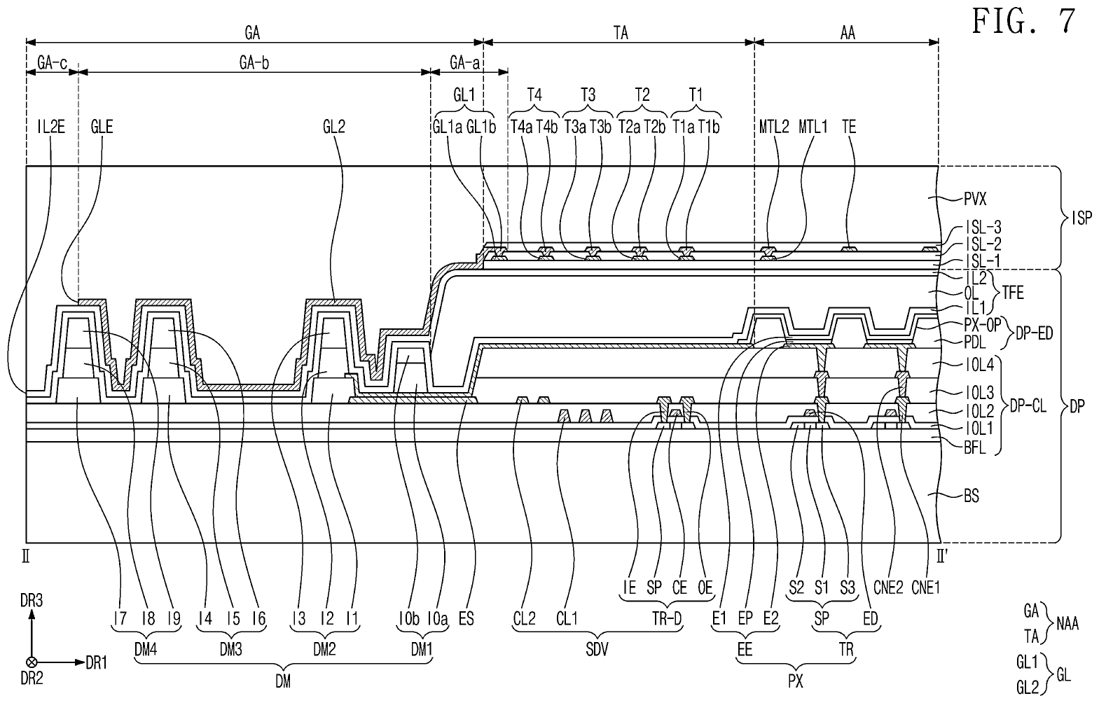

The conductive layer MTL may include sensing electrodes TE (refer to FIG. 6A), trace lines TL (refer to FIG. 6A), and a ground pattern GL (refer to FIG. 7) of the input sensing panel ISP described later.

The first sensing insulating layer ISL-1 may be disposed on the display panel DP. The second sensing insulating layer ISL-2 may be disposed on the first conductive layer MTL1. The third sensing insulating layer ISL-3 may be disposed on the second conductive layer MTL2. Each of the first sensing insulating layer ISL-1, the second sensing insulating layer ISL-2 and the third sensing insulating layer ISL-3 may include an inorganic layer. In addition, each of the first sensing insulating layer ISL-1, the second sensing insulating layer ISL-2 and the third sensing insulating layer ISL-3 may further include an organic layer.

Each of the first sensing insulating layer ISL-1, the second sensing insulating layer ISL-2 and the third sensing insulating layer ISL-3 may include at least one of silicon nitride and silicon oxynitride. In addition, the first sensing insulating layer ISL-1, the second sensing insulating layer ISL-2 and the third sensing insulating layer ISL-3 may include silicon oxide. The inorganic layer of the first sensing insulating layer ISL-1, the second sensing insulating layer ISL-2 and the third sensing insulating layer ISL-3 may include at least one of aluminum oxide, titanium oxide, zirconium oxide, and hafnium oxide. In the expressions of silicon nitride (SiNx), silicon oxynitride (SiOxNy), and silicon oxide (SiOx), each of x and y may be an integer greater than zero (0).

In the case where the first sensing insulating layer ISL-1, the second sensing insulating layer ISL-2 and the third sensing insulating layer ISL-3 include the organic layer, the organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

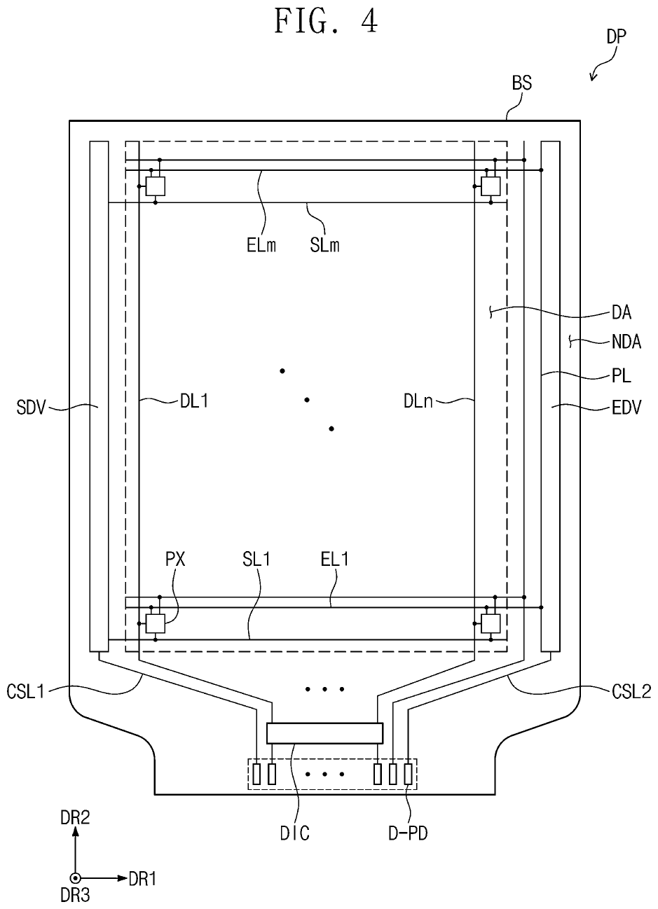

FIG. 4 is a plan view of the display panel DP according to an embodiment of the present disclosure.

Referring to FIG. 4, the display panel DP may include the base layer BS, a plurality of pixels PX, a plurality of signal lines including a plurality of scan lines SL1 to SLm, a plurality of data lines DL1 to DLn, a plurality of emission lines EL1 to ELm, first and second control lines CSL1 and CSL2, and a power line PL electrically connected to the pixels PX, a scan driver SDV, a data driver DIC, an emission driver EDV, and a plurality of panel pads D-PD.

The base layer BS may provide a base surface on which elements and lines of the display panel DP are disposed. The base layer BS may include the display area DA and the non-display area NDA. The display area DA may be an area in which the pixels PX are disposed to display the image IM (refer to FIG. 1). The non-display area NDA may be disposed adjacent to the display area DA and may be an area in which elements and lines are disposed to drive the pixels PX. The non-display area NDA may not display image.

Each of the pixels PX may include a pixel driving circuit including a plurality of transistors TR, e.g., a switching transistor, a driving transistor, etc., a capacitor and a light emitting element electrically connected to the pixel driving circuit. Each of the pixels PX may emit a light in response to electrical signals applied thereto.

Each of the scan driver SDV, the data driver DIC, and the emission driver EDV may be disposed in the non-display area NDA. However, the present disclosure is not necessarily limited thereto. In some embodiments, at least one of the scan driver SDV, the data driver DIC, and the emission driver EDV may be disposed in the display area DA, and thus, a size of the non-display area NDA may be reduced.

The signal lines SL1 to SLm, EL1 to Elm, DL1 to DLn, CSL1, CSL2, and PL may include the plurality of scan lines SL1 to SLm, the plurality of data lines DL1 to DLn, the plurality of emission lines EL1 to Elm, the first control line CSL1, the second control line CSL2, and the power line PL. Each of m and n is a natural number. Each of the pixels PX may be electrically connected to a corresponding scan line SL1 to, a corresponding data line DL1 to DLn, and a corresponding emission line EL1 to Elm. In some embodiments, more types of signal lines may be provided in the display panel DP depending on the configuration of the pixel driving circuit of the pixels PX.

The scan lines SL1 to SLm may extend in a direction opposite to the first direction DR1 and may be electrically connected to the scan driver SDV. The data lines DL1 to DLn may extend in a direction opposite to the second direction DR2 and may be electrically connected to the data driver DIC. The emission lines EL1 to Elm may extend in the first direction DR1 and may be electrically connected to the emission driver EDV.

The power line PL may include a portion extending in the first direction DR1 and a portion extending in the second direction DR2. The portion of the power line PL extending in the first direction DR1. The portion of the power line PL extending in the second direction DR2 may be electrically connected to the pixels PX and the portion of the power line PL extending in the first direction DR1. The portion of the power line PL extending in the first direction DR1 and the portion of the power line PL extending in the second direction DR2 may be disposed on the same layer and may be provided integrally with each other. In some embodiments, the portion of the power line PL extending in the second direction DR2 may be disposed on a different layer from the portion of the power line PL extending in the first direction DR1 and may be connected to the portion of the power line PL extending in the first direction DR1 via a contact hole.

The first control line CSL1 may be electrically connected to the scan driver SDV. The second control line CSL2 may be electrically connected to the emission driver EDV.

The panel pads D-PD may be disposed adjacent to a lower end of the non-display area NDA. The panel pads D-PD may be disposed closer to a lower end of the display panel DP than the data driver DIC is. For example, the panel pads D-PD may be disposed below the data driver DIC. The panel pads D-PD may be spaced apart from each other along the first direction DR1. The panel pads D-PD may be electrically connected to a circuit board that provides a signal which controls an operation of the scan driver SDV, the data driver DIC, and the emission driver EDV.

The panel pads D-PD may be display pads electrically connected to the pixels PX. Each of the panel pads D-PD may be connected to a corresponding signal lines including the plurality of scan lines SL1 to SLm, the plurality of data lines DL1 to DLn, the plurality of emission lines EL1 to ELm, the first and the second control line CSL1 and CSL2, and the power line PL As an example, the power line PL, the first and second control lines CSL1 and CSL2, and the data lines DL1 to DLn may be connected to corresponding panel pads D-PD. The data lines DL1 to DLn may be connected to the corresponding panel pads D-PD via the data driver DIC.

The scan driver SDV may generate a plurality of scan signals in response to a scan control signal. The scan signals may be applied to the pixels PX via the scan lines SL1 to SLm. The data driver DIC may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals. Accordingly, the display panel DP may display the image through the display area DA using the pixels PX.

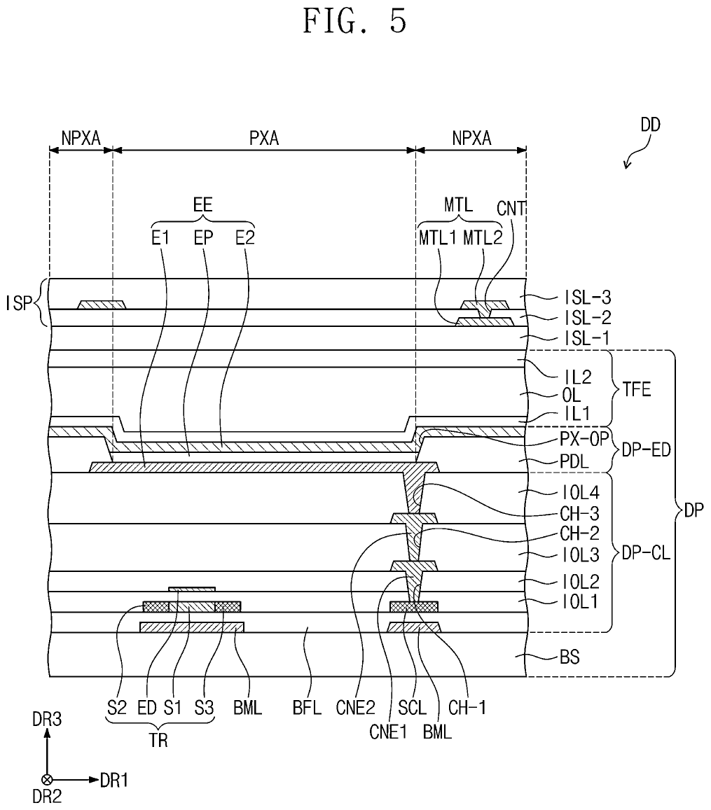

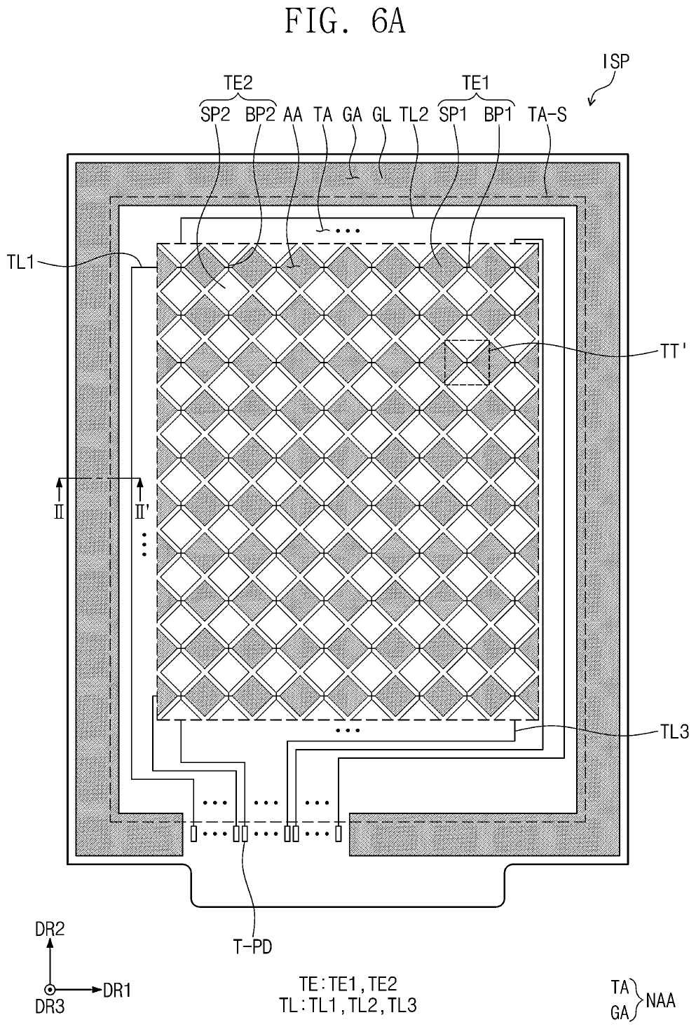

FIG. 5 is a cross-sectional view of a portion of the display device DD according to an embodiment of the present disclosure. FIG. 5 shows a cross-section of a portion of the display device DD, which includes a pixel PX (refer to FIG. 4)). For the convenience of explanation, FIG. 5 shows one transistor TR included in the pixel PX. However, the present disclosure is not necessarily limited thereto. According to an embodiment, the pixel PX may have an equivalent circuit that includes a plurality of transistors TR. The equivalent circuit of the pixel may change in various ways.

The display device DD includes the display panel DP and the input sensing panel ISP. The display panel DP may include the base layer BS, the circuit element layer DP-CL, the display element layer DP-ED, and the encapsulation layer TFE.

The display panel DP may include insulating layers, the transistor, a connection pattern, and a signal line.

A plurality of inorganic layers, a plurality of organic layers, a semiconductor layer, and a conductive layer may be formed by a coating or depositing process. Then, the inorganic layers, the organic layers, the semiconductor layer, and the conductive layer may be selectively patterned through several photolithography processes. The circuit element layer DP-CL including insulating layers formed of the inorganic layers and the organic layers, the transistor including the semiconductor pattern SP formed of the semiconductor layer, the connection pattern, and the signal line formed of the conductive layer may be formed.

Then, the display element layer DP-ED including a light emitting element EE which includes the connection pattern may be formed on the circuit element layer DP-CL. Then the encapsulation layer TFE covering the display element layer DP-ED may be formed. For example, the encapsulation layer TFE may be disposed on the display element layer DP-ED.

Referring to FIG. 5, the circuit element layer DP-CL may include a light shielding electrode BML, a buffer layer BFL, insulating layers IOL1, IOL2, IOL3, and IOL4, a transistor TR, connection electrodes CNE1 and CNE2, and a signal line SCL.

The light shielding electrode BML may be disposed on the base layer BS. The light shielding electrode BML may overlap with the transistor TR. The light shielding electrode BML may also be disposed below the signal line SCL. The light shielding electrode BML may block a light entering the transistor TR or the signal line SCL from the display panel DP and protect the semiconductor pattern SP or the connection pattern of the transistor TR and the signal line SCL. The light shielding electrode BML may include a conductive material.

The light shielding electrode BML may be connected to the power line PL (refer to FIG. 4) and may receive a voltage. When the voltage is applied to the light shielding electrode BML, a threshold voltage of the transistor TR disposed on the light shielding electrode BML may be maintained. However, the present disclosure is not necessarily limited thereto. In some embodiments, the light shielding electrode BML may be a floating electrode. In some embodiments, the light shielding electrode BML may be omitted.

The buffer layer BFL may be disposed on the base layer BS to cover the light shielding electrode BML. The buffer layer BFL may improve an adhesive force between the semiconductor pattern SP and the base layer BS or between the connection pattern and the base layer BS. The buffer layer BFL may prevent metal atoms or impurities from being diffused to the semiconductor pattern SP or the connection pattern.

The buffer layer BFL may be an inorganic layer. The buffer layer BFL may include at least one of silicon oxide, silicon nitride, and silicon oxynitride. As an example, the buffer layer BFL may have a structure in which a silicon oxide layer and a silicon nitride layer are alternately stacked on top of each other.

The transistor TR may include a source S2, an active S1, a drain S3, and a gate ED. The source S2, the active S1, and the gate ED of the transistor TR may be formed from the semiconductor pattern SP (refer to FIG. 7). The source S2 and the drain S3 may extend from the active S1 to opposite directions from each other when viewed in a cross-section. For example, the active S1 may be disposed between the source S2 and the drain S3 when viewed in a cross-section.

FIG. 5 shows a portion of the signal line SCL formed of the semiconductor pattern SP (refer to FIG. 7). The signal line SCL may be connected to the drain S3 of the transistor TR when viewed in the plane.

The semiconductor pattern SP of the transistor TR may include polysilicon, amorphous silicon, or metal oxide. However, it is not necessarily limited thereto. For example, the semiconductor pattern SP may include a variety of materials as long as the semiconductor pattern SP has a semiconductor property.

The semiconductor pattern SP may include a plurality of areas distinguished from each other depending on a conductivity. A portion of the semiconductor pattern SP, which is doped with dopant, or a portion of the semiconductor pattern SP, whether a metal oxide is reduced, may have a relatively high conductivity and may serve as the source S2 and the drain S3 of the transistor TR. A portion of the semiconductor pattern SP, which has a relatively high conductivity, may serve as an electrode or a signal line and may correspond to the source S2 and the drain S3 of the transistor TR. A non-doped or non-reduced portion with a relatively low conductivity may correspond to the active S1 of the transistor TR.

A first insulating layer IOL1 may be disposed on the buffer layer BFL. The first insulating layer IOL1 may at least partially cover the semiconductor pattern SP of the transistor TR.

The first insulating layer IOL1 may include an inorganic layer. The first insulating layer IOL1 may be referred to as a first inorganic layer. As an example, the first insulating layer IOL1 may be the inorganic layer including at least one of aluminum oxide, titanium oxide, silicon oxide, silicon nitride, silicon oxynitride, zirconium oxide, and hafnium oxide. The first insulating layer IOL1 may have a single-layer or multi-layer structure. The first insulating layer IOL1 may have a structure in which plural inorganic layers are stacked, however, it should not be necessarily limited thereto. For example, the first insulating layer IOL1 may further include an organic layer in addition to the inorganic layer.

Second, third, and fourth insulating layers IOL2, IOL3, and IO4 may have the multi-layer structure described above with reference to the first insulating layer IOL1. Accordingly, the stack structure of the insulating layer having the multi-layer structure described above may be applied to the second, third, and fourth insulating layers IOL2, IOL3, and IO4.

The gate ED may be disposed on the first insulating layer IOL1. The gate ED may overlap with the active S1 of the transistor TR. The gate ED may be used as a mask in a process of doping the semiconductor pattern SP of the transistor TR. The gate ED may include titanium (Ti), silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like. However, it should not be necessarily limited thereto.

The second insulating layer IOL2 may be disposed on the first insulating layer IOL1 and may at least partially cover the gate ED. The second insulating layer IOL2 may include an inorganic layer. The second insulating layer IOL2 may be referred to as a second inorganic layer. As an example, the second insulating layer IOL2 may include at least one of silicon oxide, silicon nitride, and silicon oxynitride. The second insulating layer IOL2 may be an inorganic layer and/or an organic layer and may have a single-layer or multi-layer structure. For example, the second insulating layer IOL2 may have a multi-layer structure of a silicon oxide layer and a silicon nitride layer.

The third insulating layer IOL3 may be disposed on the second insulating layer IOL2. The third insulating layer IOL3 may include an inorganic layer. The third insulating layer IOL3 may be referred to as a third inorganic layer. The third insulating layer IOL3 may have a single-layer or multi-layer structure. As an example, the third insulating layer IOL3 may have a multi-layer structure of a silicon oxide layer and a silicon nitride layer.

A first connection electrode CNE1 may be disposed on the third insulating layer IOL3. The first connection electrode CNE1 may be connected to the signal line SCL via a contact hole CH-1 formed through the first, second, and third insulating layers IOL1, IOL2, and IOL3.

The fourth insulating layer IOL4 may be disposed on the third insulating layer IOL3. The fourth insulating layer IOL4 may include an inorganic layer. The fourth insulating layer IOL4 may be referred to as a fourth inorganic layer. The fourth insulating layer IOL4 may have a single-layer of a silicon oxide layer. However, it is not necessarily limited thereto. In some embodiments, the fourth insulating layer IOL4 may further include an organic layer.

The fourth insulating layer IOL4 may further include organic layers disposed on the inorganic layer. The organic layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

A second connection electrode CNE2 may be disposed on the third insulating layer IOL3. The second connection electrode CNE2 may be connected to the first connection electrode CNE1 via a second contact hole CH-2 formed through the third insulating layer IOL3. For example, the second contact hole CH-2 may penetrate and be in contact with the third insulating layer IOL3. The second connection electrode CNE2 may be at least partially covered by the fourth insulating layer IOL4.

The circuit element layer DP-CL may further include a plurality of transistors TR and may further include signal lines electrically connected to the transistors TR. The signal lines may extend and connect with the panel pads D-PD (refer to FIG. 4) arranged in the non-display area NDA (refer to FIG. 4). In addition, the signal lines may extend and connect with sensing pads T-PD (refer to FIG. 6A) arranged in a peripheral area NAA (refer to FIG. 6A).

The display element layer DP-ED may be disposed on the circuit element layer DP-CL. The display element layer DP-ED may include a pixel definition layer PDL and the light emitting element EE. The light emitting element EE may include a first electrode E1, a light emitting layer EP, and a second electrode E2.

The first electrode E1 may be disposed on the fourth insulating layer IOL4. The first electrode E1 may be connected to the second connection electrode CNE2 via a third contact hole CH-3 defined through the fourth insulating layer IOL4. The first electrode E1 may be electrically connected to the drain S3 of the transistor TR through the first and second connection electrodes CNE1 and CNE2.

The first electrode E1 may be referred to as a pixel electrode. The first electrode E1 may be formed of a metal material, metal alloy, or conductive compound. The first electrode E1 may be an anode or a cathode. The first electrode E1 may be a transmissive electrode, a transflective electrode, or a reflective electrode. In the case where the first electrode E1 is the transmissive electrode, the first electrode E1 may include a transparent metal oxide such as indium tin oxide (ITO), indium zinc oxide (IZO), zinc oxide (ZnO), indium tin zinc oxide (ITZO), etc. In the case where the first electrode E1 is the transflective electrode or the reflective electrode, the first electrode E1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof.

In some embodiments, the first electrode E1 may have a multi-layer structure of a reflective layer or a semi-transmissive layer, which is formed of the above-mentioned material, and a transparent conductive layer formed of indium tin oxide (ITO), indium zinc oxide (IZO), zinc oxide (ZnO), or indium tin zinc oxide (ITZO). As an example, the first electrode E1 may have a three-layer structure of ITO, Ag, and ITO. However, it is not necessarily limited thereto.

In some embodiments, the first electrode E1 may include the above-mentioned metal materials, a combination of two or more metal materials selected from the above-mentioned metal materials, or oxides of the above-mentioned metal materials.

The pixel definition layer PDL may be disposed on the fourth insulating layer IOL4. The pixel definition layer PDL may be provided with a pixel opening PX-OP which exposes a portion of the first electrode E1. Light emitting areas PXA may be distinguished from non-light-emitting areas NPXA by the pixel definition layer PDL. The display device DD may include the light emitting areas PXA and the non-light-emitting area NPXA, and the non-light-emitting area NPXA may include the pixel definition layer PDL. A portion corresponding to the first electrode E1 exposed through the pixel opening PX-OP may be defined as the light emitting area PXA.

The pixel definition layer PDL may be formed of a polymer resin. As an example, the pixel definition layer PDL may include a polyacrylate-based resin or a polyimide-based resin. The pixel definition layer PDL may further include an inorganic material. The pixel definition layer PDL may include a light absorbing material or a black pigment or dye. The pixel definition layer PDL including the black pigment or dye may implement a black pixel definition layer. When the pixel definition layer PDL is formed, a carbon black may be used as the black pigment or dye, however, the present disclosure is not necessarily limited thereto.

In some embodiments, the pixel definition layer PDL may include an inorganic material such as silicon nitride (SiNx), silicon oxide (SiOx), or silicon oxynitride (SiOxNy).

The light emitting layer EP may be disposed on the first electrode E1 in the light emitting element EE. The light emitting layer EP may provide a light having at least one of red, blue, and green colors.

The second electrode E2 may be disposed on the light emitting layer EP. The second electrode E2 may be disposed over the pixels PX (refer to FIG. 5). The second electrode E2 may be referred to as a common electrode. The second electrode E2 may be a cathode or an anode. As an example, when the first electrode E1 is an anode, the second electrode E2 may be a cathode, and when the first electrode E1 is a cathode, the second electrode E2 may be an anode.

The second electrode E2 may be a transmissive electrode, a transflective electrode, or a reflective electrode. In a case where the second electrode E2 is the transmissive electrode, the second electrode E2 may include a transparent metal oxide such as indium tin oxide (ITO), indium zinc oxide (IZO), zinc oxide (ZnO), indium tin zinc oxide (ITZO), etc. In addition, the second electrode E2 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof.

A hole control layer may be disposed between the first electrode E1 and the light emitting layer EP. The hole control layer may include a hole transport layer and may further include a hole injection layer. An electron control layer may be disposed between the light emitting layer EP and the second electrode E2. The electron control layer may include an electron transport layer and may further include an electron injection layer. The hole control layer and the electron control layer may be commonly formed over the plural pixels PX (refer to FIG. 4) using an open mask.

The encapsulation layer TFE may be disposed on the display element layer DP-ED. The encapsulation layer TFE may include a first encapsulation inorganic layer IL1, an encapsulation organic layer OL, and a second encapsulation inorganic layer IL2, which are sequentially stacked. However, layers included in the encapsulation layer TFE are not necessarily limited thereto and may further include an organic layer or an inorganic layer.

The encapsulation inorganic layers IL1 and 1IL2 may protect the display element layer DP-ED from moisture and oxygen, and the encapsulation organic layer OL may protect the display element layer DP-ED from a foreign substance such as dust particles. The encapsulation inorganic layers IL1 and 1IL2 may include at least one of silicon nitride, silicon oxynitride, silicon oxide, titanium oxide, or aluminum oxide. The encapsulation organic layer OL may include an acrylic-based organic layer, however, materials for the encapsulation inorganic layers IL1 and 1IL2 and the encapsulation organic layer OL are not necessarily limited thereto.

The input sensing panel ISP may be disposed on the encapsulation layer TFE. As described with reference to FIG. 3, the input sensing panel ISP may include the first, second and third sensing insulating layers ISL-1, ISL-2, and ISL-3 and the first and second conductive layers MTL1 and MTL2.

FIG. 5 shows the structure in which the input sensing panel ISP has a multi-layer structure of the first conductive layer MTL1 and the second conductive layer MTL2. The second conductive layer MTL2 may be connected to the first conductive layer MTL1 via a contact hole CNT. For example, the contact hole CNT may vertically extend and connect the first conductive layer MTL1 to the second conductive layer MTL2. However, the present disclosure is not necessarily limited thereto. In some embodiments, the input sensing panel ISP may a single-layer structure of a conductive layer. In this case, one of the second sensing insulating layer ISL-2 and the third sensing insulating layer ISL-3 may be omitted.

FIG. 6A is a plan view of the input sensing panel ISP according to an embodiment of the present disclosure.

The input sensing panel ISP may include an active area AA and a peripheral area NAA defined adjacent to the active area AA.

The active area AA may correspond to the display area DA (refer to FIG. 1) of the display device DD (refer to FIG. 1). The sensing electrodes TE of the input sensing panel ISP may be disposed in the active area AA and may sense the external input.

The peripheral area NAA may include a trace area TA adjacent to the active area AA and a ground area GA spaced apart from the active area AA with the trace area TA interposed therebetween.

The peripheral area NAA may correspond to the non-display area NDA (refer to FIG. 1) of the display device DD (refer to FIG. 1). Elements and lines may be disposed in the peripheral area NAA and drive the sensing electrodes TE disposed in the active area AA.

The input sensing panel ISP may include the sensing electrodes TE, the trace lines TL, and a ground pattern GL, and the sensing pads T-PD.

The sensing electrodes TE may be disposed in the active area AA. The sensing electrodes TE may include first sensing electrodes TE1 and second sensing electrodes TE2 electrically insulated from the first sensing electrodes TE1 while intersecting the first sensing electrodes TE1 when viewed in the plane. The input sensing panel ISP may obtain information about the external input based on a variation in mutual capacitance between the first sensing electrodes TE1 and the second sensing electrodes TE2.

Each of the first sensing electrodes TE1 may extend along the first direction DR1, and the first sensing electrodes TE1 may be arranged along the second direction DR2. For example, the first sensing electrodes TE1 may be arranged in a plurality of rows along the second direction DR2. FIG. 6A shows ten first sensing electrodes TE1 arranged along the second direction DR2 as a representative example. However, the number of the first sensing electrodes TE1 included in the input sensing panel ISP is not necessarily limited thereto.

Each of the second sensing electrodes TE2 may extend along the second direction DR2, and the second sensing electrodes TE2 may be arranged along the first direction DR1. The second sensing electrodes TE2 may be arranged in a plurality of columns arranged along the first direction DR1. FIG. 6A shows eight second sensing electrodes TE2 arranged along the first direction DR1 as a representative example. However, the number of the second sensing electrodes TE2 included in the input sensing panel ISP is not necessarily limited thereto.

Each of the first sensing electrodes TE1 may include first sensing patterns SP1 and first connection patterns BP1. The first sensing patterns SP1 may be arranged along the first direction DR1. The first connection patterns BP1 may connect the first sensing patterns SP1 adjacent to each other along the first direction DR1. The first connection patterns BP1 may be disposed on the same layer as the first sensing patterns SP1, may extend from the first sensing patterns SP1 when viewed in the plane, and may be provided integrally with the first sensing patterns SP1. The first sensing patterns SP1 and the first connection patterns BP1 may be formed of the same conductive layer by patterning the conductive layer through the same process. However, the first connection patterns BP1 is not necessarily limited thereto as long as the first connection patterns BP1 electrically connect the first sensing patterns SP1 adjacent to each other along the first direction DR1.

Each of the second sensing electrodes TE2 may include second sensing patterns SP2 and second connection patterns BP2. The second sensing patterns SP2 may be arranged along the second direction DR2. The second connection patterns BP2 may connect the second sensing patterns SP2 adjacent to each other along the second direction DR2. The second connection patterns BP2 may be disposed on a different layer from the second sensing patterns SP2 and may be connected to corresponding second sensing patterns SP2 through contact holes CNT (refer to FIG. 6C). The second sensing patterns SP2 spaced apart from each other along the second direction DR2 may be electrically connected to each other through the second connection patterns BP2. The second connection patterns BP2 disposed on a different layer from the second sensing patterns SP2 and electrically connecting the second sensing patterns SP2 may be defined as bridge patterns.

The first sensing patterns SP1, the first connection patterns BP1, and the second sensing patterns SP2 may be disposed on the same layer. The second connection patterns BP2 and the second sensing patterns SP2 may be disposed on different layers from each other. As an example, the first sensing patterns SP1, the first connection patterns BP1, and the second sensing patterns SP2 may be included in the second conductive layer MTL2 (refer to FIG. 5), and the second connection patterns BP2 may be included in the first conductive layer MTL1 (refer to FIG. 5).

However, the present disclosure is not necessarily limited thereto. In some embodiments, the first sensing patterns SP1, the first connection patterns BP1, and the second sensing patterns SP2 may be included in the first conductive layer MTL1, and the second connection patterns BP2 may be included in the second conductive layer MTL2. In some embodiments, the first sensing patterns SP1, the second sensing patterns SP2, and the second connection patterns BP2 may be disposed on the same layer, and the first connection patterns BP1 and the first sensing patterns SP1 may be disposed on different layers from each other.

The trace lines TL may include first trace lines TL1, second trace lines TL2, and third trace lines TL3.

Each of the first trace lines TL1 may be connected to the first sensing electrodes TE1. Each of the first trace lines TL1 may be connected to the first sensing electrodes TE1 arranged in a corresponding row.

The first trace lines TL1 may be connected to left or right ends of the first sensing electrodes TE1. FIG. 6 shows the structure in which the first trace lines TL1 are connected to the left ends of the first sensing electrodes TE1 as a representative example. However, the connection of the first trace lines TL1 to the first sensing electrodes TE1 is not necessarily limited thereto.

Each of the first trace lines TL1 may extend downward from a corresponding first sensing electrode TE1 and may be connected to the sensing pads T-PD in the peripheral area NAA.

The second trace lines TL2 may be connected to upper ends of the second sensing electrodes TE2. The second trace lines TL2 may be connected to the upper ends of the second sensing electrodes TE2 arranged in a corresponding column among the second sensing electrodes TE2 arranged in the plural columns. Each of the second trace lines TL2 may extend from an upper end of a corresponding second sensing electrode TE2, and the second trace lines TL2 may be respectively connected to the sensing pads T-PD in the peripheral area NAA.

The third trace lines TL3 may be respectively connected to lower ends of the second sensing electrodes TE2. The third trace lines TL3 may be respectively connected to the lower ends of the second sensing electrodes TE2 arranged in a corresponding column among the second sensing electrodes TE2 arranged in the plural columns. Each of the third trace lines TL3 may extend from a lower end of a corresponding second sensing electrode TE2, and the third trace lines TL3 may be respectively connected to the sensing pads T-PD in the peripheral area NAA.

According to an embodiment, a length in the second direction DR2 of the second sensing electrode TE2 may be greater than a length in the first direction DR1 of the first sensing electrode TE1. However, since the second sensing electrode TE2 is connected to the second trace line TL2 and the third trace line TL3, the second sensing electrode TE2 having a relatively longer length than that of the first sensing electrode TE1 may have uniform sensitivity for the entire area thereof.

The sensing pads T-PD may be arranged in a direction opposite to the first direction DR1 on one side of the first sensing insulating layer ISL-1 in the peripheral area NAA. The sensing pads T-PD may be arranged spaced apart from each other.

The sensing pads T-PD may be electrically connected to a circuit board that provides a driving signal. The sensing pads T-PD may be electrically connected to the trace lines TL, respectively. The sensing pads T-PD may apply signals to the sensing electrodes TE via the trace lines TL. The sensing pads T-PD may receive signals from the sensing electrodes TE.

The sensing pads T-PD may be provided integrally with the trace lines TL connected thereto. That is, different from the sensing pads T-PD and the trace lines TL shown in FIG. 6A, the sensing pads T-PD and the trace lines TL might not be distinguished from each other and an end of the trace lines TL may serve as a sensing pad portion that is connected to a driving chip of the circuit board.

The sensing pads T-PD and the trace lines TL may be formed from the conductive layer MTL (refer to FIG. 5) of the input sensing panel ISP. As an example, the sensing pads T-PD and the trace lines TL may be formed through the same process as the first conductive layer MTL1, however, the present disclosure should not be limited thereto or thereby. Depending on locations where the sensing electrodes TE are placed, the sensing pads T-PD and the trace lines TL may be formed through the same process as the second conductive layer MTL2, or some of the sensing pads T-PD and some of the trace lines TL may be formed through the same process as the first conductive layer MTL1 and some of the sensing pads T-PD and some of the trace lines TL may be formed through the same process as the second conductive layer MTL2.

An outer portion TA-S of the trace area TA may correspond to a boundary between the trace area TA and the ground area GA. As shown in FIG. 6A, the outer portion TA-S of the trace area TA may have a rectangular shape. For the convenience of explanation, the outer portion TA-S of the trace area TA is represented by a dotted line in FIG. 6A. However, the present disclosure should not be limited thereto or thereby.

The ground pattern GL may be disposed in the trace area TA and the ground area GA. The ground pattern GL may overlap at least one side among sides forming the outer portion TA-S of the trace area TA. FIG. 6A shows a structure in which the ground pattern GL overlaps four sides forming the outer portion TA-S of the trace area TA as a representative example, however, the present disclosure should not be limited thereto or thereby.

The ground pattern GL may have an integral shape when viewed in the plane. FIG. 6A shows a structure in which the ground pattern GL has the integral shape surrounding the trace area TA except areas in which the sensing pads T-PD are disposed. However, the present disclosure is not necessarily limited thereto. The ground pattern GL may include sub-patterns. This will be described later with reference to FIG. 7C.

FIG. 6B is an enlarged plan view of an area TT′ of FIG. 6A. FIG. 6C is a cross-sectional view of the input sensing panel taken along a line III-III′ of FIG. 6B.

FIG. 6B shows an arrangement relationship between the first sensing patterns SP1, the first connection patterns BP1, the second sensing patterns SP2, and the second connection patterns BP2.

According to the present embodiment, the second sensing patterns SP2 and the first sensing electrodes TE1 (refer to FIG. 6A) may include mesh lines MSL. The mesh lines MSL may include a first mesh line MSL1 extending in a fourth direction DR4 and a second mesh line MSL2 extending in a fifth direction DR5.

The first and second mesh lines MSL1 and MSL2 might not overlap the light emitting area PXA described with reference to FIG. 5 and may overlap the non-light-emitting area NPXA described with reference to FIG. 5. The first and second mesh lines MSL1 and MSL2 may define a plurality of mesh openings MSL-OP. The first and second mesh lines MSL1 and MSL2 may have a line width ranging from several nanometers to several micrometers. The mesh openings MSL-OP may correspond to the light emitting areas PXA defined in each pixel PX in a one-to-one correspondence.

The second sensing patterns SP2 and the first sensing electrodes TE2 may be portions of the second conductive layer MTL2 described with reference to FIG. 6A.

The first sensing electrodes TE1 may include the first sensing patterns SP1 and the first connection patterns BP1 extending from the first sensing patterns SP1 and provided integrally with the first sensing patterns SP1. That is, the first sensing patterns SP1 and the first connection patterns BP1 may be provided integrally with each other after being pattered through the same process. However, for the convenience of explanation, the first sensing patterns SP1 and the first connection patterns BP1 will be described separately.

The second sensing electrodes TE2 (refer to FIG. 6A) may include the second sensing patterns SP2 and the second connection patterns BP2 connecting the second sensing patterns SP2 adjacent to each other. The first sensing patterns SP1, the first connection patterns BP1, and the second sensing patterns SP2 may be disposed on the same layer. The second connection patterns BP2 may be disposed on a different layer from the second sensing patterns SP2. However, the second connection patterns BP2 may be connected to the second sensing patterns SP2 via a contact hole CNT.

FIG. 6C shows a structure in which the first sensing patterns SP1 and the second sensing patterns SP2 are disposed on the second sensing insulating layer ISL-2. The second sensing patterns SP2 are connected to a corresponding second connection pattern BP2 via the contact hole CNT defined through the second sensing insulating layer ISL-2 as a representative example. Accordingly, even though the second sensing patterns SP2 are disposed on the same layer as the first sensing electrode TE1, the second sensing patterns SP2 may be insulated from the first sensing electrode TE1 by the second connection pattern BP2 disposed on the first sensing insulating layer ISL-1. Accordingly, the second connection pattern BP2 and the first sensing pattern SP1, which are disposed on different layers from each other, may overlap each other when viewed in the plane.

A portion of each of the trace lines TL1, TL2, and TL3 (refer to FIG. 6A) may be included in the second conductive layer MTL2, and the other portion of each of the trace lines TL1, TL2, and TL3 (refer to FIG. 6A) may be included in the first conductive layer MTL1. The lines disposed on different layers from each other may be connected to each other via the contact hole CNT defined through the second sensing insulating layer ISL-2, however, the present disclosure is not necessarily limited thereto. In some embodiments, the trace lines TL1, TL2, and TL3 may be included in only one of the first conductive layer MTL1 and the second conductive layer MTL2.

FIG. 7 is a cross-sectional view of a portion of the display device taken along a line II-II′ of FIG. 6A.

Referring to FIG. 7, the display device DD (refer to FIG. 1) may include the display panel DP and the input sensing panel ISP disposed on the display panel DP. In FIG. 7, to the extent that an element has not been described in detail herein, it may be assumed that the element is at least similar to corresponding elements that have been described in FIGS. 2 to 5.

The display panel DP may include the base substrate BS and the insulating layers IOL1, IOL2, IOL3, and IOL4 disposed on the base substrate BS. Components that form the pixel PX, the signal lines including the plurality of scan lines SL1 to SLm, the plurality of data lines DL1 to DLn, the plurality of emission lines EL1 to ELm, the first and the second control lines CSL1 and CSL2, and the power line PL (refer to FIG. 4), and the scan driving circuit SDV may be disposed between the base substrate BS and the insulating layers IOL1, IOL2, IOL3, and IOL4.

The pixels PX may be disposed on the first insulating layer IOL1. FIG. 7 shows components of the pixel PX as a representative example. The pixel PX may include the transistor TR and the light emitting element EE.

The scan driving circuit SDV may include a driving transistor TR-D, first signal lines CL1, and second signal lines CL2.

The driving transistor TR-D may be disposed on the first insulating layer IOL1 The driving transistor TR-D may include a semiconductor pattern SP, a gate CE, a source IE, and a drain OE. Each of the gate CE, the source IE, and the drain OE may be formed as an electrode and may be formed independent from the semiconductor pattern SP. The source IE and the drain OE may be disposed on the second insulating layer IOL2 and may be connected to the semiconductor pattern SP which penetrates the second insulating layer IOL2.

In some embodiments, the driving transistor TR-D may have substantially the same structure as the transistor TR of the pixel PX. In this case, the driving transistor TR-D may be formed through the same process as the transistor TR of the pixel PX. Thus, processes of forming the driving transistor TR-D may be simplified, and a process cost may be reduced.

The first signal lines CL1 and the second signal lines CL2 may be disposed on different layers from each other. For example, the first signal lines CL1 may be disposed on the same layer as the gate CE, and the second signal lines CL2 may be disposed on the same layer as the source IE or the drain OE. The first signal lines CL1 and the second signal lines CL2 may electrically connect the driving transistor TR-D to other components of the scan driving circuit SDV. However, this is merely an example. In some embodiments, the first signal lines CL1 or the second signal lines CL2 may be omitted.

A power pattern ES may be disposed in the peripheral area NAA. The power pattern ES may be electrically connected to the second electrode E2. The power pattern ES may provide a power voltage to the second electrode E2.

Referring to FIG. 7, the input sensing panel ISP may include the active area AA, the trace area TA adjacent to the active area AA, and the ground area GA spaced apart from the active area AA with the trace area TA interposed therebetween.

The display panel DP may further include a dam portion DM. The dam portion DM may overlap the ground area GA and may be disposed on the second insulating layer IOL2. However, the layer on which the dam portion DM is disposed is not necessarily limited thereto as long as the dam portion DM prevents the encapsulation organic layer OL from overflowing.

The dam portion DM may include first, second, third, and fourth dam portions DM1, DM2, DM3, and DM4. The first, second, third, and fourth dam portions DM1, DM2, DM3, and DM4 may be sequentially arranged along a direction away from the active area AA, which is opposite to the first direction DR1. The number of the dam portions of the dam portion DM is not necessarily limited.

The dam portion DM may prevent the encapsulation organic layer OL from overflowing during a process of forming the encapsulation organic layer OL. The dam portion DM may include multiple layers. As an example, the first dam portion DM1 may include two layers I0a and I0b, the second dam portion DM2 may include three layers I1, I2, and I3, the third dam portion DM3 may include three layers 14, 15, and 16, the fourth dam portion DM4 may include three layers 17, 18, and 19.

Each of the dam portions DM1, DM2, DM3, and DM4 may include plural layers. However, the dam portion DM may have various structures and is not necessarily limited.

The input sensing panel ISP may include the sensing electrodes TE, the trace lines TL connected to the sensing electrodes TE, and the ground pattern GL.

The sensing electrodes TE may be disposed in the active area AA. The sensing electrodes TE may be portions of the first conductive layer MTL1 or the second conductive layer MTL2. FIG. 7 shows the structure in which some portions of the sensing electrodes TE as the portions of the second conductive layer MTL2 as a representative example, however, the present disclosure is not necessarily limited thereto.

As described with reference to FIG. 6A, the sensing electrodes TE may include the first sensing electrodes TE1 (refer to FIG. 6A) and the second sensing electrodes TE2 (refer to FIG. 6A). The input sensing panel ISP may include the sensing electrodes TE and may sense the external input.

The trace lines TL (refer to FIG. 6A) may be arranged in the trace area TA. The trace lines TL may be portions of the first conductive layer MTL1 or the second conductive layer MTL2. FIG. 7 shows the structure in which the trace lines TL as the portions of the first conductive layer MTL1 and the second conductive layer MTL2 as a representative example, however, the it is not necessarily limited thereto. For example, each of the trace lines TL may be a portion of the first conductive layer MTL1 or the second conductive layer MTL2.

As described with reference to FIG. 6A, the trace lines TL may include the first, second, and third trace lines TL1, TL2, and TL3 (refer to FIG. 6A). For the convenience of explanation, descriptions will be focused on the first trace line TL1 in FIG. 7, and descriptions of components and structures in cross-section of the first trace line TL1 may correspond to descriptions of components and structures in cross-section of the second trace line TL2 (refer to FIG. 6A) and the third trace line TL3 (refer to FIG. 6A).

FIG. 7 shows a cross-section of first-first, first-second, first-third, and first-fourth trace lines T1, T2, T3, and T4 included in the first trace line TL1 as a representative example. When viewed in the cross-section, the first-first, first-second, first-third, and first-fourth trace lines T1, T2, T3, and T4 may be sequentially arranged along a direction away from the active area AA. For example, the first-first trace line T1 may be disposed closest to the active area AA and the first-fourth trace line T4 may be disposed closest to the ground area GA.

When viewed in the cross-section, the first-first, first-second, first-third, and first-fourth trace lines T1, T2, T3, and T4 may be spaced apart from each other. In addition, at least a portion of the sensing insulating layer ISL may be disposed between the first-first, first-second, first-third, and first-fourth trace lines T1, T2, T3, and T4. Accordingly, the first-first, first-second, first-third, and first-fourth trace lines T1, T2, T3, and T4 may be insulated from each other.

Referring to FIG. 7, the first-first trace line T1 may include a first-first lower trace line T1a and a first-first upper trace line T1b, the first-second trace line T2 may include a first-second lower trace line T2a and a first-second upper trace line T2b, the first-third trace line T3 may include a first-third lower trace line T3a and a first-third upper trace line T3b, and the first-fourth trace line T4 may include a first-fourth lower trace line T4a and a first-fourth upper trace line T4b.

However, the present disclosure is not limited thereto. In some embodiments, at least a trace line of the first-first, first-second, first-third, and first-fourth trace lines T1, T2, T3, and T4 may include only one of corresponding upper and lower trace lines.

The first-first, first-second, first-third, and first-fourth lower trace lines T1a, T2a, T3a, and T4a may be portions of the first conductive layer MTL1, and the first-first, first-second, first-third, and first-fourth upper trace lines T1b, T2b, T3b, and T4b may be portions of the second conductive layer MTL2.

The ground pattern GL may be disposed in the trace area TA and the ground area GA. For example, the ground pattern GL may include a first ground portion GL1 disposed in the trace area TA and a second ground portion GL2 disposed in the ground area GA.

The first ground portion GL1 may include a first lower ground GL1a included in the first conductive layer MTL1 or a first upper ground GL1b included in the second conductive layer MTL2. The second ground portion GL2 may be extension of the first upper ground GL1b or the first lower ground GL1a towards an opposite to the first direction DR1. For example, the second ground portion GL2 may extend from the trace area TA to the ground area GA.

In the present embodiment, the first ground portion GL1 may include the first lower ground GL1a and the first upper ground GL1b, and the second ground portion GL2 may be a portion extending from the first upper ground GL1b. However, the present disclosure is not necessarily limited thereto, and the second ground portion GL2 may be a portion extending from the first lower ground GL1a.

The first ground portion GL1 may be disposed in the trace area TA and may be spaced apart from the trace lines TL. The trace lines TL might not be disposed between the first ground portion GL1 and the ground area GA, and the trace lines TL may be disposed in an area close to the active area AA with respect to the first ground portion GL1. Accordingly, the ground pattern GL may be disposed further away than other trace lines TL from the first-first trace line T1 which may be disposed at an outermost portion among the trace lines TL in the input sensing panel ISP.

At least a portion of the ground pattern GL may overlap the encapsulation organic layer OL, and the other portion of the ground pattern GL might not overlap the encapsulation organic layer OL.

In the present embodiment, a portion of the second ground portion GL2 may overlap the encapsulation organic layer OL, and the other portion of the second ground portion GL2 might not overlap the encapsulation organic layer OL. However, the present disclosure is not necessarily limited thereto. In some embodiments, the second ground portion GL2 may entirely overlap the encapsulation organic layer OL.

At least a portion of the ground pattern GL may overlap the encapsulation organic layer OL at a portion where a cross-sectional thickness of the encapsulation organic layer OL is changed. In the present disclosure, the expression “the cross-sectional thickness of the encapsulation organic layer OL is changed.” means that the thickness of the encapsulation organic layer OL increases or decreases in the cross-section of the encapsulation organic layer OL in a direction toward the outer portion of the display device DD (refer to FIG. 1).

The ground pattern GL may overlap the dam portion DM. FIG. 7 shows the structure in which the ground pattern GL overlaps the first, second, third, and fourth dam portions DM1, DM2, DM3, and DM4 as a representative example. However, the present disclosure is not necessarily limited thereto. For example, the ground pattern GL may overlap only a portion of the first, second, third, and fourth dam portions DM1, DM2, DM3, and DM4.

The ground area GA may include a first ground area GA-a in which the first ground pattern GL1 is disposed and overlaps the encapsulation organic layer OL, a second ground area GA-b in which the second ground pattern GL2 is disposed and does not overlap the encapsulation organic layer OL, and a third ground area GA-c in which the ground pattern GL is not disposed.

The dam portion DM may be covered by the second encapsulation inorganic layer IL2. For example, the first, second, third, and fourth dam portions DM1, DM2, DM3, and DM4 may be covered by the second encapsulation inorganic layer IL2.

The second encapsulation inorganic layer IL2 may be at least partially covered by the ground pattern GL. As an example, the second encapsulation inorganic layer IL2 may be covered by the second ground pattern GL2 in the first ground area GA-a and the second ground area GA-b, and the second encapsulation inorganic layer IL2 might not be covered by the second ground pattern GL2 in the third ground area GA-c.

In an area overlapping the dam portion DM, at least a portion of the second encapsulation inorganic layer IL2 may be exposed without being covered by the ground pattern GL. For example, the second encapsulation inorganic layer IL2 may be covered by the second ground pattern GL2 in areas overlapping the first, second, and third dam portions DM1, DM2, and DM3, and the second encapsulation inorganic layer IL2 may be exposed without being covered by the second ground pattern GL2 in an area overlapping the fourth dam portion DM4. Accordingly, a portion of the second encapsulation inorganic layer IL2, which is exposed without being covered by the second ground pattern GL2, may be in direct contact with a passivation layer PVX.

When viewed in the plane, an end GLE of the ground pattern GL might not be aligned with an end IL2E of the second encapsulation inorganic layer IL2. As the second encapsulation inorganic layer IL2 is not completely covered by the second ground pattern GL2, the end IL2E of the second encapsulation inorganic layer IL2 and the end GLE of the ground pattern GL might not be aligned with each other.

The ground pattern GL may be a portion of the first conductive layer MTL1 or a portion of the second conductive layer MTL2. Accordingly, the ground pattern GL may include substantially the same material as the first conductive layer MTL1 or the second conductive layer MTL2. As an example, the ground pattern GL may include molybdenum, silver, titanium, copper, aluminum, or alloys thereof.

Since the ground pattern GL is not disposed in the third ground area GA-c, defects occurring in the manufacturing process of the display device DD (refer to FIG. 1) may be prevented. The manufacturing process of the display device DD may include a process of cutting a mother glass into a shape corresponding to the display device DD.

Since the input sensing panel ISP of the display device DD includes the third ground area GA-c where the ground pattern GL is not disposed at the outermost portion, the ground pattern GL may be prevented from being cut when the mother glass is cut to manufacture the display device DD. Therefore, the ground pattern GL may be prevented from being cut and from being lifted-off from the second encapsulation inorganic layer IL2.

The input sensing panel ISP may further include the passivation layer PVX.

The passivation layer PVX may be disposed on the third sensing insulating layer ISL-3 and the ground pattern GL. The passivation layer PVX may include a lower surface that is curved and an upper surface that is flat. The lower surface of the passivation layer PVX may have a curved shape corresponding to a shape of the third sensing insulating layer ISL-3 and a shape of the ground pattern GL.

The input sensing panel ISP may further include a guard line disposed between the ground pattern GL and the trace line TL. Due to a difference in electric potential between the ground pattern GL and the trace lines TL, a coupling phenomenon may occur between the ground pattern GL and the trace line TL, and thus, noises may occur. The guard line disposed between the ground pattern GL and the trace line TL may prevent the noises caused by the coupling phenomenon. The guard line may be further disposed between the first, second, and third trace lines TL1, TL2, and TL3.

The ground pattern GL may be formed by a deposition process. As an example, the ground pattern GL may be formed by depositing a metal material through a sputtering process. The ground pattern GL may be formed through the same process as the trace lines TL. The ground pattern GL may be formed by depositing the metal material in the first, second, and third ground areas GA-a, GA-b, and GA-c and partially etching the metal material in the third ground area GA-c. Accordingly, the ground pattern GL is formed without a separate and additional process, and thus, process time and costs may be reduced.

Since the input sensing panel ISP operates in response to a voltage, a touch sensitivity of the display device DD (refer to FIG. 1) may decrease when the input sensing panel ISP is affected by electromagnetic interference (EMI).

The ground pattern GL may prevent the input sensing panel ISP from being affected by electromagnetic interference (EMI).

As an example, the ground pattern GL may prevent an external static electricity from exerting an influence on the input sensing panel ISP. The ground pattern GL may be connected to a ground terminal of a flexible printed circuit (FPC). In this case, the external static electricity may be discharged to the ground terminal via the ground pattern GL of the display device DD (refer to FIG. 1). Accordingly, the ground pattern GL may prevent the external static electricity from exerting an influence on the sensing electrodes TE and the trace lines TL.

The input sensing panel ISP may further include a ground voltage pad. The ground voltage pad may provide a ground voltage to the ground pattern GL. Accordingly, it is possible to prevent signal defects such as noise, which is caused by the electrical signal provided to the display panel DP, from occurring in the input sensing panel ISP. Thus, the deterioration of the touch sensitivity of the input sensing panel ISP may be prevented.

Referring to FIG. 7, the ground pattern GL may be disposed in the first ground area GA-a and the second ground area GA-b and may be disposed over a relatively larger area compared to the sensing electrodes TE and the trace lines TL. Accordingly, the ground pattern GL may have a low resistance, and thus, the static electricity may be discharged. In addition, when the ground pattern GL acts as a storage battery as described later, an electrical capacity may increase.

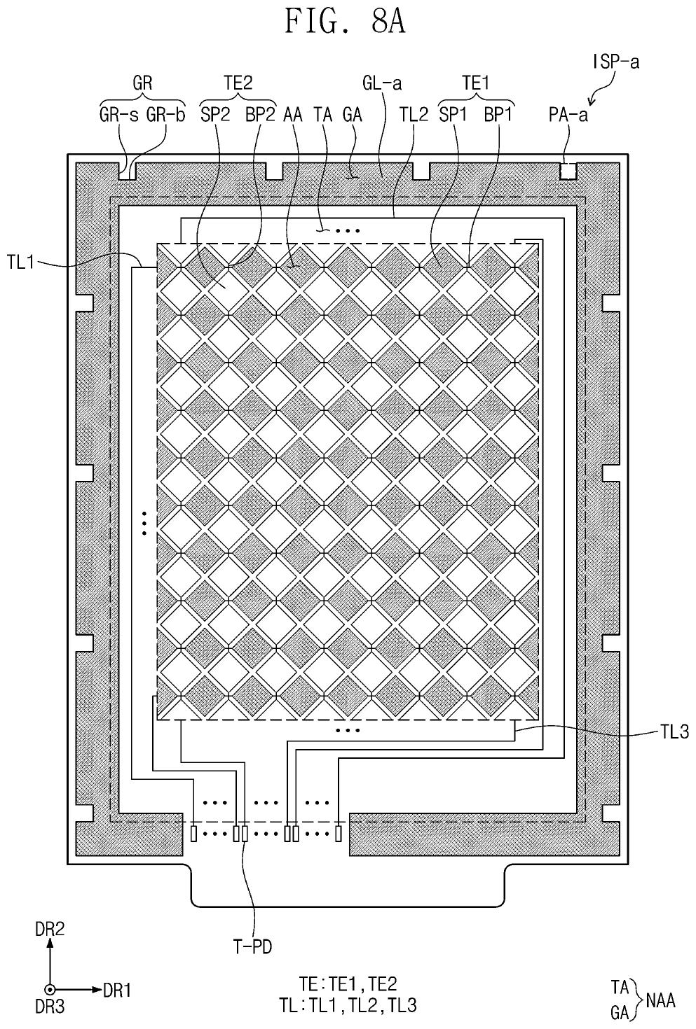

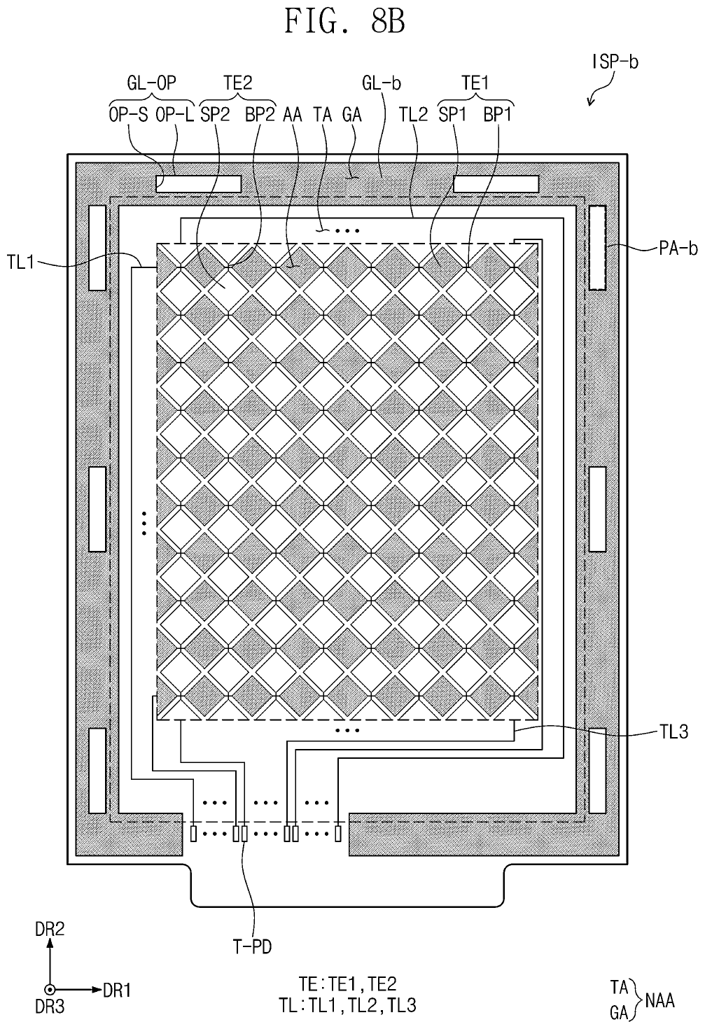

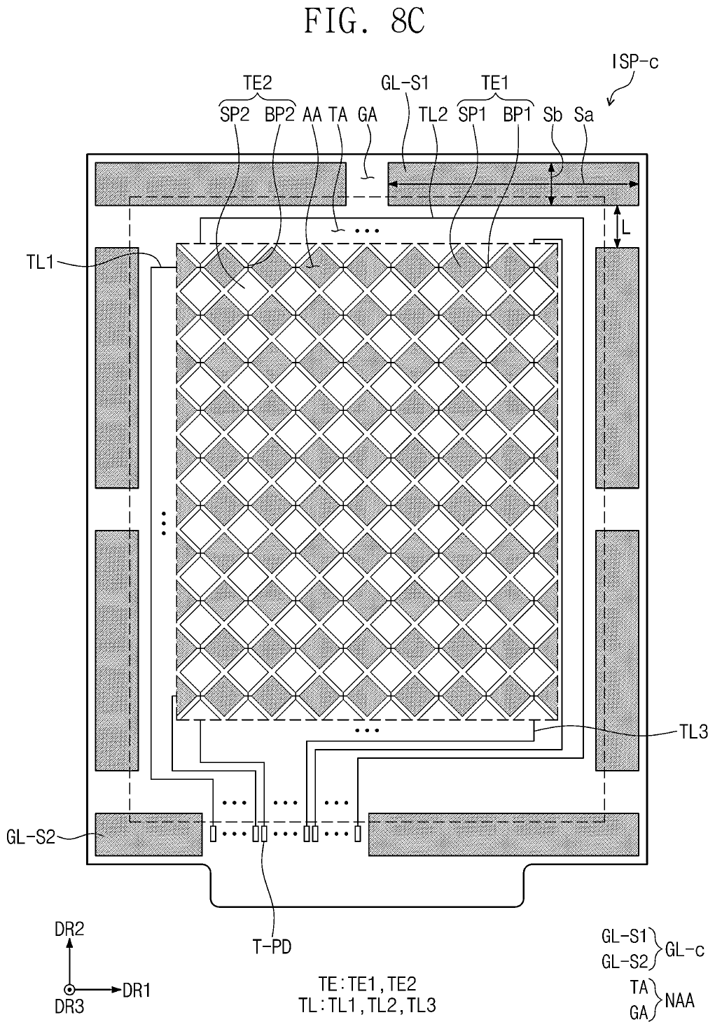

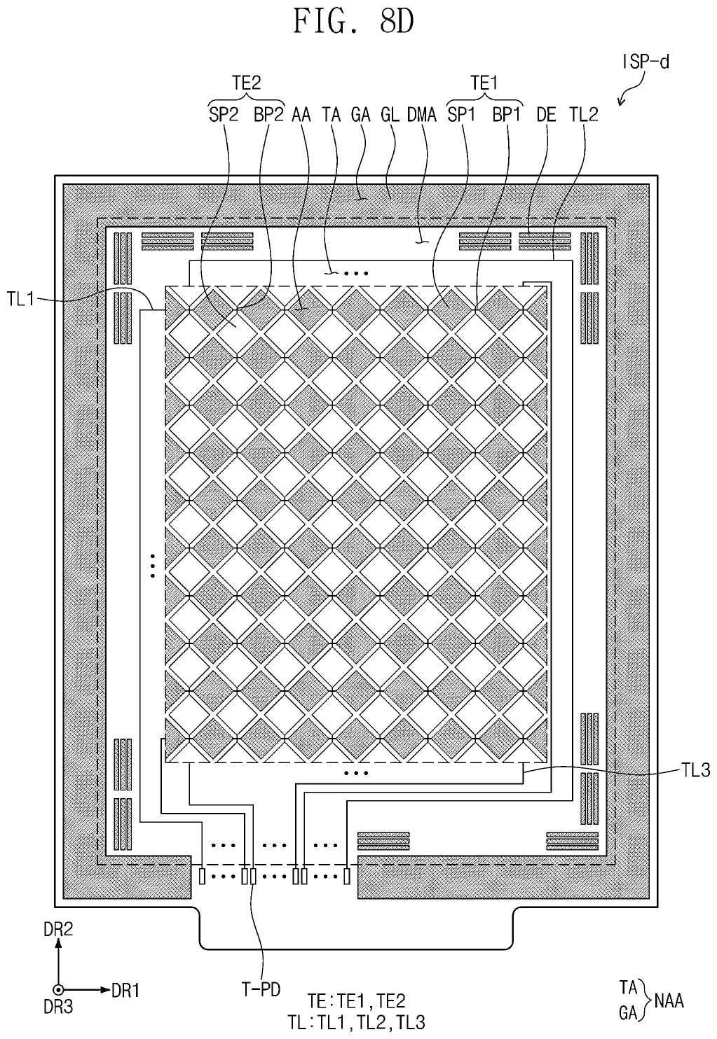

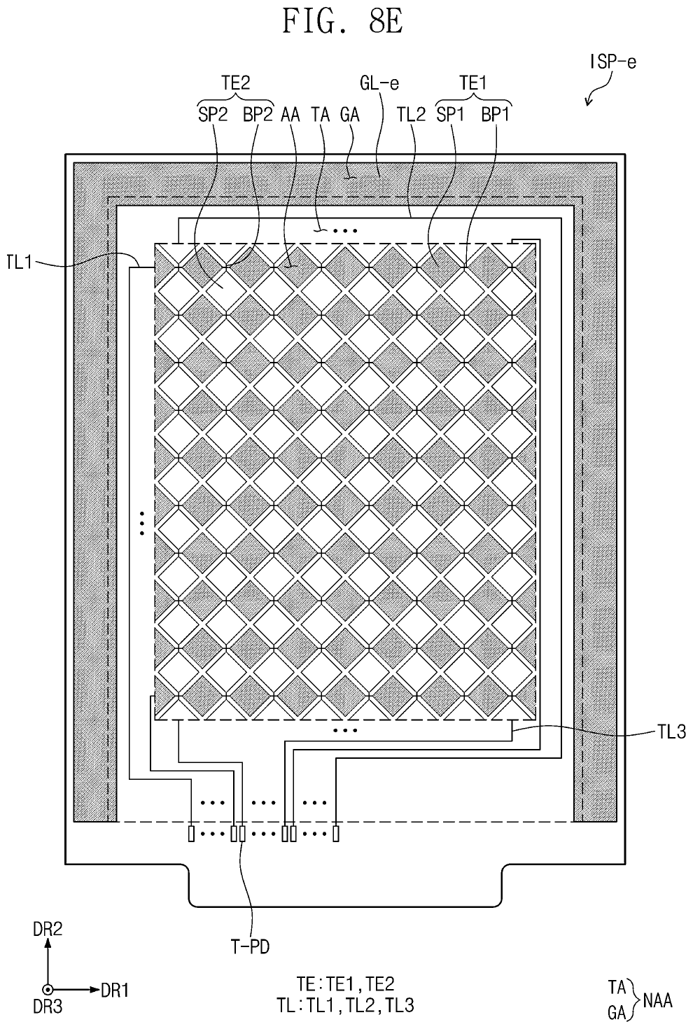

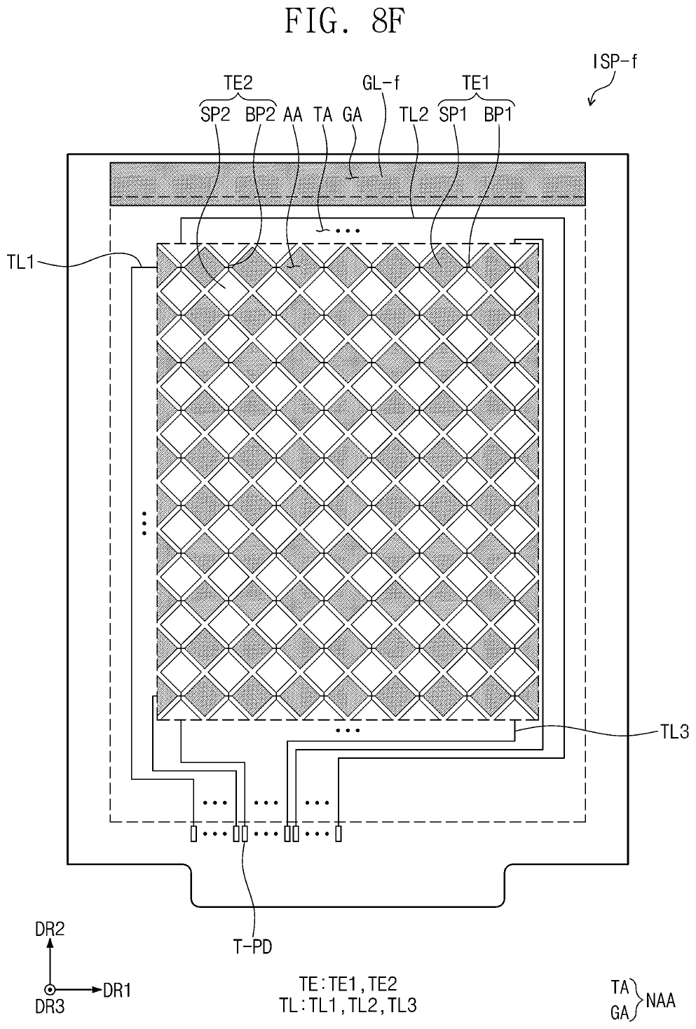

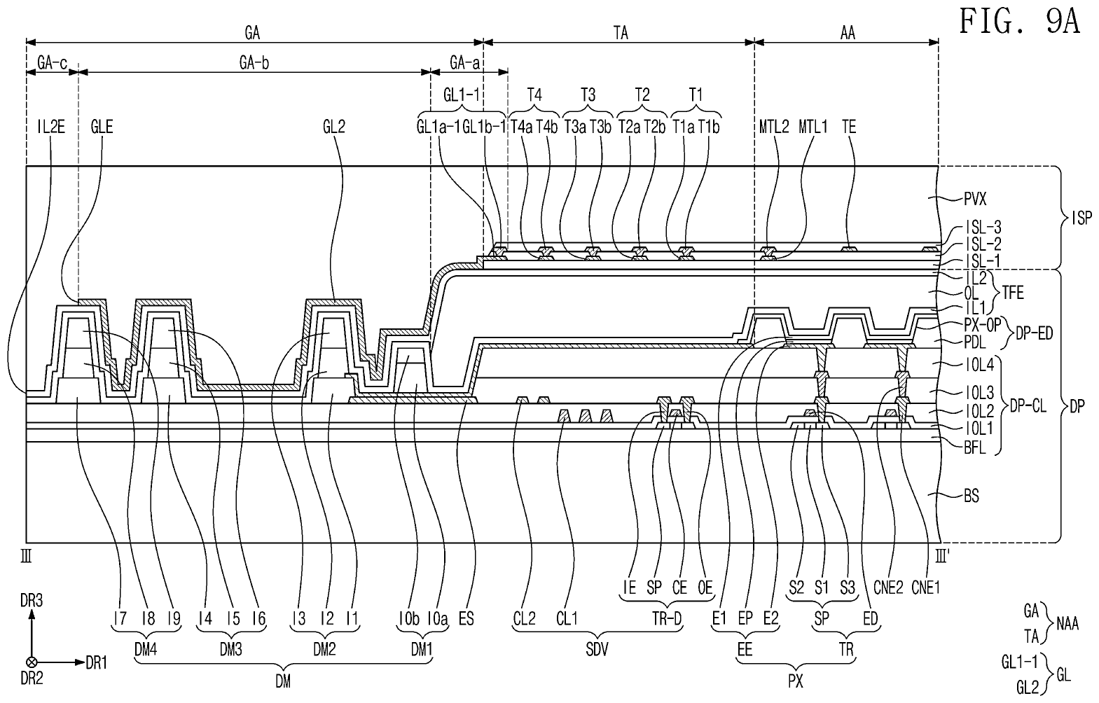

FIG. 8A is a plan view of an input sensing panel ISP-a according to an embodiment of the present disclosure.

The input sensing panel ISP-a may include an active area AA and a peripheral area NAA adjacent to the active area AA. The input sensing panel ISP-a may include sensing electrodes TE, trace lines TL, a ground pattern GL-a, and sensing pads T-PD.

In FIG. 8A, the same/similar reference numerals denote the same/similar elements in FIG. 6A, and thus, detailed descriptions of the same/similar elements will be omitted.

Referring to FIG. 8A, the ground pattern GL-a may be disposed in a trace area TA and a ground area GA. The ground pattern GL-a may overlap at least one side of sides that form an outer portion TA-S(refer to FIG. 6A) of the trace area TA. FIG. 8A shows a structure in which the ground pattern GL-a overlaps four sides forming the outer portion TA-S(refer to FIG. 6A) of the trace area TA as a representative example, however, the present disclosure is not necessarily limited thereto.

The ground pattern GL-a may be provided with a groove pattern GR defined therein and recessed in a direction from the outer portion of the input sensing panel ISP-a towards the active area AA.

The groove pattern GR may be defined in plural number, and the groove patterns GR may be spaced apart from each other. FIG. 8A shows a structure in which the outer portion TA-S at a right side of the trace area TA faces four groove patterns GR, the outer portion TA-S at an upper side of the trace area TA faces four groove patterns GR, and the outer portion TA-S at a left side of the trace area TA faces four groove patterns GR as a representative example, however, the present disclosure is not necessarily limited thereto.

Each of the groove patterns GR may include a lower side GR-b and a lateral side GR-s. When viewed in the cross-section, a pattern area PA-a may be defined between the lower side GR-b and the lateral side GR-s of each of the groove patterns GR. At least a portion of the second encapsulation inorganic layer IL2 (refer to FIG. 7) may be exposed through the pattern area PA-a.

The groove patterns GR might not completely penetrate the ground pattern GLa. Accordingly, the ground pattern GLa may have an integral shape when viewed in the plane. FIG. 8A shows the structure in which the ground pattern GL has the integral shape surrounding the trace area TA except the area where the sensing pads T-PD are disposed.

As shown in FIG. 8A, the pattern area PA-a may have a quadrangular shape, however, the shape of the pattern area PA-a is not necessarily limited to the quadrangular shape. As an example, the pattern area PA-a may have a polygonal shape or a semicircular shape.

FIG. 8B is a plan view of an input sensing panel ISP-b according to an embodiment of the present disclosure.

The input sensing panel ISP-b may include an active area AA and a peripheral area NAA adjacent to the active area AA. The input sensing panel ISP-b may include sensing electrodes TE, trace lines TL, a ground pattern GL-b, and sensing pads T-PD.

In FIG. 8B, to the extent that an element has not been described in detail herein, it may be assumed that the element is at least similar to corresponding elements that have been described in FIG. 6A.

The ground pattern GL-b may be disposed in a trace area TA and a ground area GA. The ground pattern GL-b may overlap at least one side that form an outer portion TA-S (refer to FIG. 6A) of the trace area TA. FIG. 8B shows a structure in which the ground pattern GL-b overlaps four sides forming the outer portion TA-S(refer to FIG. 6A) of the trace area TA as a representative example, however, the present disclosure is not necessarily limited thereto.

The ground pattern GL-b may be provided with openings GL-OP defined therethrough and spaced apart from each other. The openings GL-OP may be defined in plural, however, the present disclosure is not necessarily limited thereto.

FIG. 8B shows a structure in which the outer portion TA-S at a right side of the trace area TA is adjacent to three openings GL-OP, the outer portion TA-S at a left side of the trace area TA is adjacent to three openings GL-OP, and the outer portion TA-S at an upper side of the trace area TA is adjacent to two openings GL-OP, however, the present disclosure is not necessarily limited thereto.

A pattern area PA-b may be defined between a first side OP-L and a second side OP-S. At least a portion of a second encapsulation inorganic layer IL2 (refer to FIG. 7) may be exposed through the pattern area PA-b.

Each of the openings GL-OP may include the first sides OP-L extending along the same direction as a direction in which a side forming the outer portion TA-S of the trace area TA adjacent to the openings GL-OP extends and the second sides OP-S extending along a direction intersecting the direction in which the first sides OP-L extend. Accordingly, each of the openings GL-OP may extend in the same direction as the direction in which the side forming the outer portion TA-S of the trace area TA adjacent to the openings GL-OP extends.

FIG. 8B shows a structure in which the openings GL-OP adjacent to the outer portion TA-S at the left or right side of the trace area TA extend along the second direction DR2 and the openings GL-OP adjacent to the outer portion TA-S at the upper side of the trace area TA extend along the first direction DR1 as a representative example, however, the present disclosure is not necessarily limited thereto.

As shown in FIG. 8B, the pattern area PA-b may have a quadrangular shape, however, the shape of the pattern area PA-b is not necessarily limited to the quadrangular shape. As an example, the pattern area PA-b may have a polygonal shape or a circular shape.

As the openings GL-OP are defined through the ground pattern GL-b, cracks may be prevented from occurring in the ground pattern GL-b. As an example, even though cracks occur in a direction from an outer portion of the ground pattern GL-b to the active area AA, the cracks might not be formed continuously and may be interrupted where the cracks are in contact with the openings GL-OP.

FIG. 8C is a plan view of an input sensing panel ISP-c according to an embodiment of the present disclosure.

The input sensing panel ISP-c may include an active area AA and a peripheral area NAA adjacent to the active area AA. The input sensing panel ISP-c may include sensing electrodes TE, trace lines TL, a ground pattern GL-c, and sensing pads T-PD.

In FIG. 8C, to the extent that an element has not been described in detail herein, it may be assumed that the element is at least similar to corresponding elements that have been described in FIG. 6A.

The ground pattern GL-c may be disposed in a trace area TA and a ground area GA. The ground pattern GL-c may overlap at least one side that form an outer portion TA-S (refer to FIG. 6A) of the trace area TA. FIG. 8C shows a structure in which the ground pattern GL-b overlaps four sides forming the outer portion TA-S(refer to FIG. 6A) of the trace area TA as a representative example, however, the present disclosure is not necessarily limited thereto.

The trace area TA may have a rectangular shape, and the ground pattern GL-c may include a first sub-pattern GL-S1 and a second sub-pattern GL-S2, which at least partially overlaps the sides forming the outer portion TA-S of the trace area TA.

Referring to FIG. 8C, the ground pattern GL-c may include the first sub-pattern GL-S1 whose length in an extension direction is relatively long and the second sub-pattern GL-S2 whose length in an extension direction is shorter than the length in the extension direction of the first sub-pattern GL-S1. However, the present disclosure is not necessarily limited thereto. In some embodiments, the ground pattern GL-c may include a single type of sub-pattern or two or more types of sub-patterns.

Each of the first and second sub-patterns GL-S1 and GL-S2 may have a shape extending along the same direction as a direction in which the side forming the outer portion TA-S of the trace area TA overlapping therewith extends. FIG. 8C shows a structure in which two sub-patterns extending in the second direction DR2 are disposed at each of right and left sides of the active area AA and two sub-patterns extending in the first direction DR1 are disposed at each of upper and lower sides of the active area AA as a representative example. However, the present disclosure is not necessarily limited thereto.

The first and second sub-patterns GL-S1 and GL-S2 may be spaced apart from each other and may at least partially surround the trace area TA. FIG. 8C shows a structure in which the first and second sub-patterns GL-S1 and GL-S2 are spaced apart from other first and second sub-patterns GL-S1 and GL-S2 by a separation distance L.

Each of the first and second sub-patterns GL-S1 and GL-S2 may have a rectangular shape. As shown in FIG. 8C, each of the first and second sub-patterns GL-S1 and GL-S2 may have the rectangular shape extending along the same direction as the side forming the outer portion TA-S of the trace area TA overlapping therewith extends, however, the present disclosure is not necessarily limited thereto.

FIG. 8D is a plan view of an input sensing panel ISP-d according to an embodiment of the present disclosure.

In FIG. 8D, to the extent that an element has not been described in detail herein, it may be assumed that the element is at least similar to corresponding elements that have been described in FIG. 6A.

The input sensing panel ISP-d may include a trace area TA, and the trace area TA may include a dummy area DMA adjacent to a ground area GA.

The input sensing panel ISP-d may include sensing electrodes TE, trace lines TL, a ground pattern GL, sensing pads T-PD, and dummy electrodes DE. The dummy electrodes DE may be spaced apart from the trace line TL and may be disposed in the dummy area DMA.

The dummy electrodes DE may be electrically floating.

The dummy pattern may have a rectangular shape extending in one direction. The dummy pattern may be provided in plural in the dummy area DMA. The dummy patterns DE may be spaced apart from each other, and the dummy patterns DE, the trace line TL, and the ground pattern GL may be spaced apart from each other. Accordingly, the dummy pattern DE may be electrically insulated from the trace line TL and the ground pattern GL.

FIG. 8D shows the dummy pattern DE having a rectangular shape with long sides extending along the one direction, however, the present disclosure is not necessarily limited thereto.

FIG. 8E is a plan view of an input sensing panel ISP-e according to an embodiment of the present disclosure.

The input sensing panel ISP-e may include an active area AA and a peripheral area NAA adjacent to the active area AA. The input sensing panel ISP-e may include sensing electrodes TE, trace lines TL, a ground pattern GL-e, and sensing pads T-PD.

In FIG. 8E, to the extent that an element has not been described in detail herein, it may be assumed that the element is at least similar to corresponding elements that have been described in FIG. 6A.

The ground pattern GL-e may be disposed in the trace area TA and the ground area GA. The ground pattern GL-e may overlap at least one side that form an outer portion TA-S(refer to FIG. 6A) of the trace area TA. FIG. 8E shows a structure in which the ground pattern GL-e overlaps upper, right, and left sides of the four sides forming the outer portion TA-S(refer to FIG. 6A) of the trace area TA as a representative example. The ground pattern GL-e might not overlap a lower side of the four sides.

FIG. 8F is a plan view of an input sensing panel ISP-f according to an embodiment of the present disclosure.

The input sensing panel ISP-f may include an active area AA and a peripheral area NAA adjacent to the active area AA. The input sensing panel ISP-f may include sensing electrodes TE, trace lines TL, a ground pattern GL-f, and sensing pads T-PD.

In FIG. 8F, to the extent that an element has not been described in detail herein, it may be assumed that the element is at least similar to corresponding elements that have been described in FIG. 6A.

The ground pattern GL-f may be disposed in a trace area TA and a ground area GA. The ground pattern GL-f may overlap at least one side of that form an outer portion TA-S (refer to FIG. 6A) of the trace area TA. FIG. 8F shows a structure in which the ground pattern GL-f overlaps an upper side of the four sides forming the outer portion TA-S(refer to FIG. 6A) of the trace area TA as a representative example. The ground pattern GL-f might not overlap lower, right, and left sides of the four sides forming the outer portion TA-S(refer to FIG. 6A) of the trace area TA.

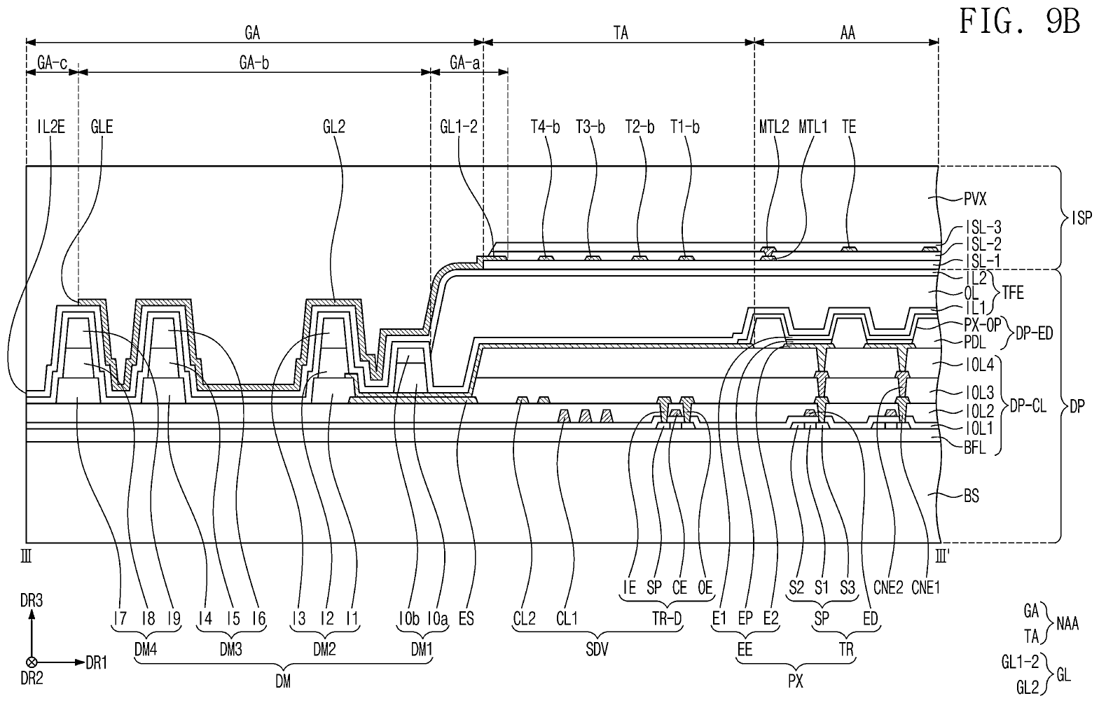

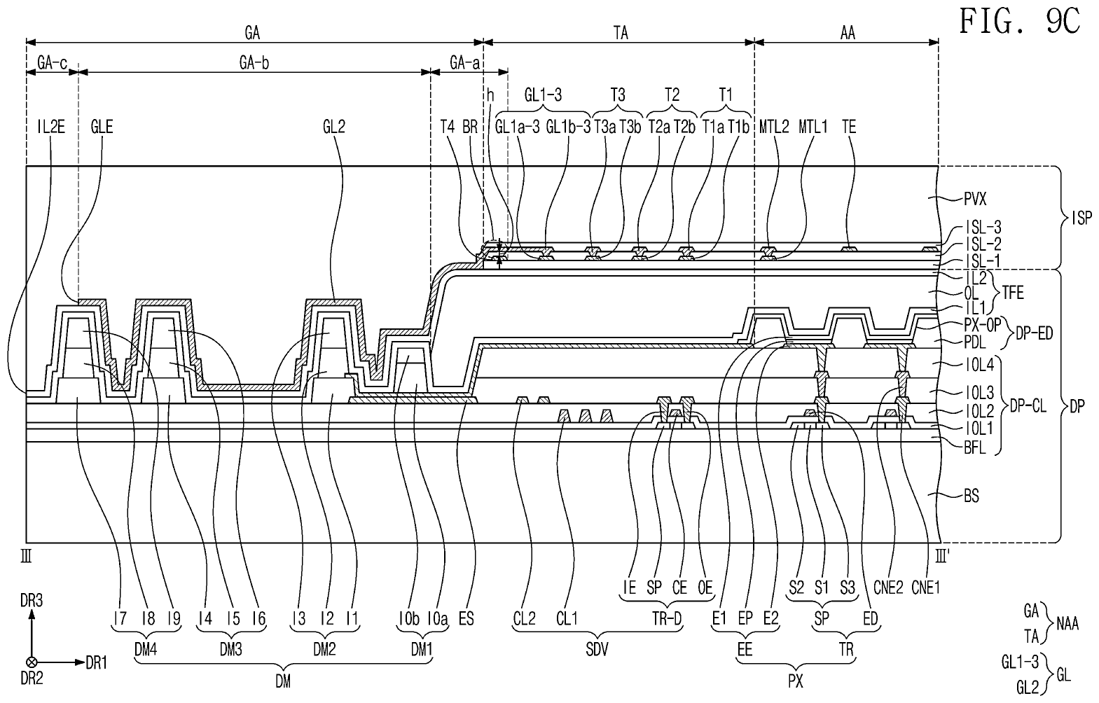

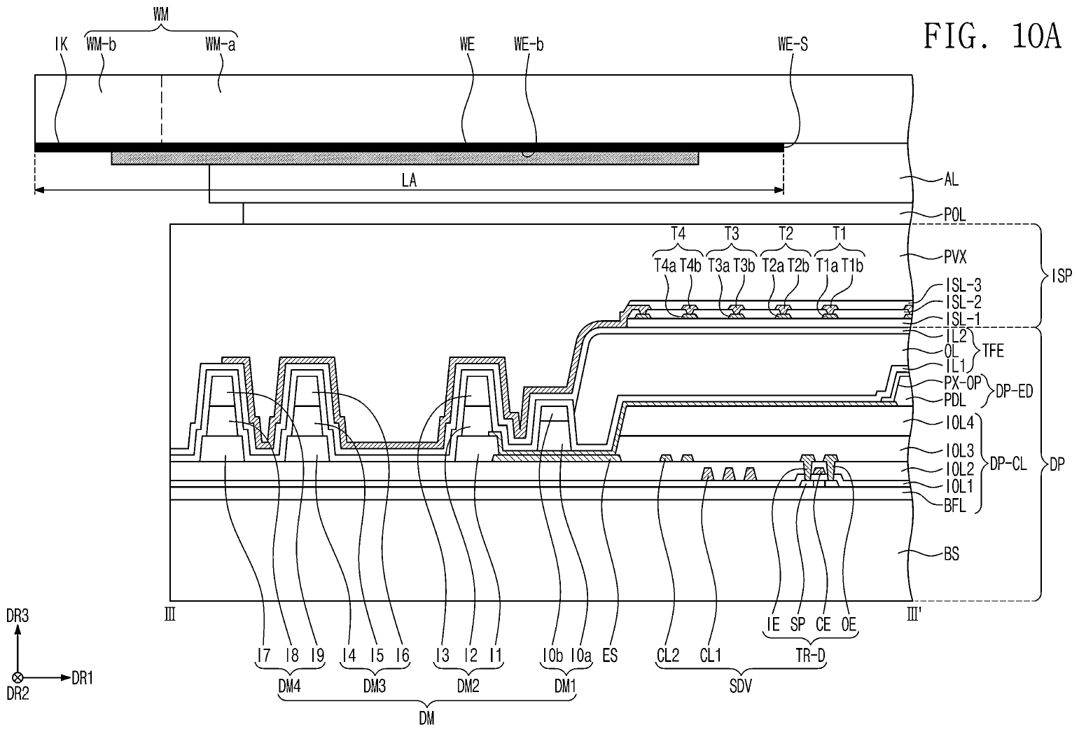

FIG. 9A is a cross-sectional view of a display device according to an embodiment of the present disclosure.

In FIG. 9A, to the extent that an element has not been described in detail herein, it may be assumed that the element is at least similar to corresponding elements that have been described in FIG. 7.

Referring to FIG. 9A, an input sensing panel ISP may include an active area AA, a trace area TA defined adjacent to the active area AA, and a ground area GA spaced apart from the active area AA with the trace area TA interposed therebetween.

In the input sensing panel ISP, a first ground portion GL1-1 may include a first lower ground GL1a-1 and a first upper ground GL1b-1, and a second ground portion GL2 may be a portion formed by elongating the first lower ground GL1a-1.

FIG. 9B is a cross-sectional view of a display device according to an embodiment of the present disclosure.

In FIG. 9B, to the extent that an element has not been described in detail herein, it may be assumed that the element is at least similar to corresponding elements that have been described in FIG. 7.

In an input sensing panel ISP, a first ground portion GL1-2 may include a first lower ground GL1a (refer to FIG. 7) and might not include a first upper ground GL1b (refer to FIG. 7). A second ground portion GL2 may be a portion formed by elongating the first ground portion GL1-2.

FIG. 9C is a cross-sectional view of a display device according to an embodiment of the present disclosure.

In FIG. 9C, to the extent that an element has not been described in detail herein, it may be assumed that the element is at least similar to corresponding elements that have been described in FIG. 7.

In the display device, a first ground portion GL1-3 may include a bridge portion BR overlapping at least one of trace lines TL, and the trace line TL (refer to FIG. 6A) overlapping the bridge portion BR may be spaced apart from the bridge portion BR with a second sensing insulating layer ISL-2 interposed therebetween.

Referring to FIG. 9C, a contact hole, which connects a first conductive layer MTL1 and a second conductive layer MTL2, might not be defined through a first-fourth trace line T4 between the bridge portion BR and a second sensing insulating layer ISL-2. Accordingly, the first-fourth trace line T4 may be spaced apart from the bridge portion BR with the second sensing insulating layer ISL-2 interposed therebetween by an insulation distance h. Therefore, the first-fourth trace line T4 may be electrically insulated from the bridge portion BR.

FIG. 9C shows a structure in which one trace line TL overlaps the bridge portion BR, however, the present disclosure is not necessarily limited thereto or thereby. In some embodiments, the trace line TL overlapping the bridge portion BR may be provided in plural.

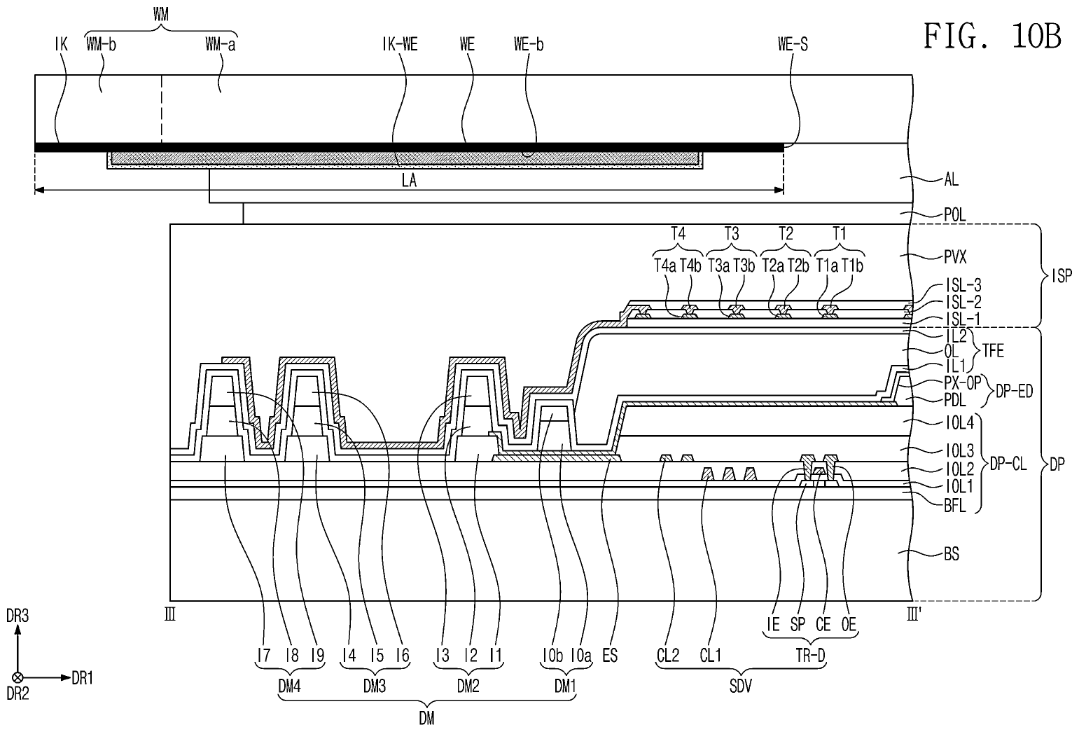

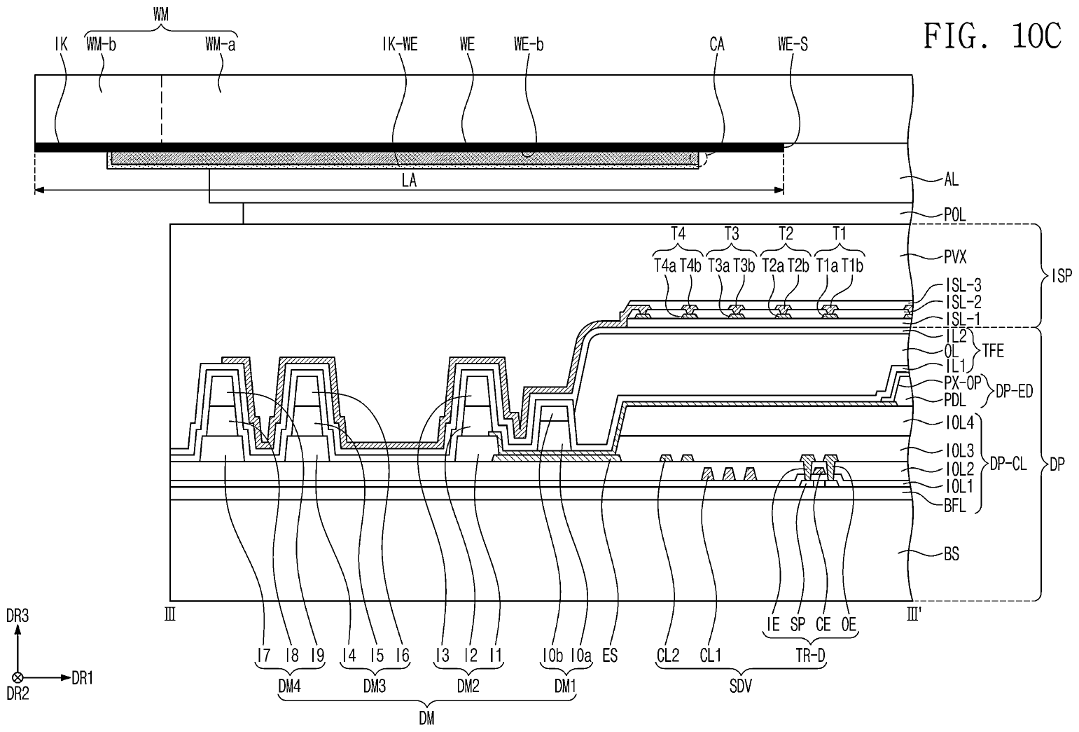

FIG. 10A is a cross-sectional view of a display device according to an embodiment of the present disclosure.

The display device may include a display panel DP, an input sensing panel ISP disposed on the display panel DP, an optical layer POL disposed on the input sensing panel ISP, and a cover window WM disposed on the optical layer POL. An adhesive layer AL may be disposed between the cover window WM and the optical layer POL. The cover window WM may be coupled with the input sensing panel ISP by the adhesive layer AL.

The cover window WM may include a first portion WM-a that overlaps the display panel DP and a second portion WM-b that does not overlap the display panel DP. The second portion WM-b may correspond to a protrusion portion of the cover window WM, which laterally protrudes relative to the display panel DP.

A light blocking pattern IK may be disposed on a lower surface of the cover window WM to overlap the second portion WM-b of the cover window WM or a ground pattern GL (refer to 7). An area of the cover window WM where the light blocking pattern IK is disposed may be defined as a light blocking area LA.

A light blocking pattern IK may be an area which an ink is coated on.

The light blocking pattern IK may be a color layer formed on the lower surface of the cover window WM. The light blocking pattern IK may include a material with a color. As an example, the light blocking pattern IK may include a colored organic layer. The light blocking pattern IK may have a single-layer or multi-layer structure. The light blocking area LA of the cover window WM where the light blocking pattern IK is disposed may have a relatively low light transmittance compared to the active area AA. As described above, since the light blocking pattern IK includes the colored material in a peripheral area NAA, components of the display panel DP may be prevented from being viewed by the user through the cover window WM.

The display device may further include a window electrode WE disposed between the display panel DP and the cover window WM.

The window electrode WE may be disposed under the cover window WM and may at least partially overlap the light blocking area LA. In addition, the window electrode WE may at least partially overlap the ground pattern GL. The window electrode WE may include a metal material. Accordingly, the window electrode WE may have a conductivity.

Since each of the window electrode WE and the ground pattern GL corresponds to a conductive electrode, charges may be stored between the window electrode WE and the ground pattern GL, which are arranged parallel to each other. Accordingly, the window electrode WE and the ground pattern GL may act as an EMI suppression capacitor.

The cover window WM may include the first portion WM-a, and a space where the window electrode WE disposed may expand towards the outside of the display panel DP. Therefore, an area of the window electrode WE may increase, and a capacitance of the window electrode WE and the ground pattern GL may increase. Accordingly, an EMI suppression effect by the window electrode WE and the ground pattern GL may increase.

FIG. 10B is a cross-sectional view of a display device according to an embodiment of the present disclosure.

The display device may include a display panel DP, an input sensing panel ISP disposed on the display panel DP, an optical layer POL disposed on the input sensing panel ISP, and a cover window WM disposed on the optical layer POL. An adhesive layer AL may be disposed between the cover window WM and the optical layer POL. The cover window WM may be coupled with the input sensing panel ISP by the adhesive layer AL.

In FIG. 10B, to the extent that an element has not been described in detail herein, it may be assumed that the element is at least similar to corresponding elements that have been described in FIGS. 7 and 10A.

An electrode light blocking pattern IK-WE may be disposed on a lower surface and a side surface of a window electrode WE. The electrode light blocking pattern IK-WE may prevent a light emitted from the display panel DP from being reflected from the lower surface and the side surface of the window electrode WE. Additionally, the electrode light blocking pattern IK-WE may prevent a light from being viewed by the user.

FIG. 10C is a cross-sectional view of a display device according to an embodiment of the present disclosure.

The display device may include a display panel DP, an input sensing panel ISP disposed on the display panel DP, an optical layer POL disposed on the input sensing panel ISP, and a cover window WM disposed on the optical layer POL. An adhesive layer AL may be disposed between the cover window WM and the optical layer POL. The cover window WM may be coupled with the input sensing panel ISP by the adhesive layer AL.

In FIG. 10C, to the extent that an element has not been described in detail herein, it may be assumed that the element is at least similar to corresponding elements that have been described in FIGS. 7, 10A, and 10B.

A connection area CA may be defined in a lower surface or a side surface of a window electrode WE, and an electrode light blocking pattern IK-WE may be disposed on the lower surface and the side surface of the window electrode WE except the connection area CA. FIG. 10C shows the structure in which the electrode light blocking pattern IK-WE is formed on the side surface of the window electrode WE, however, the present disclosure is not necessarily limited thereto.

The display device may include a conducting line whose one end is in contact with the window electrode WE in the connection area CA and the other end is in contact with a ground pattern GL (refer to FIG. 7) that connects the window electrode WE and the ground pattern GL (refer to FIG. 7). Accordingly, not only the ground pattern GL but also the window electrode WE may have a ground potential.

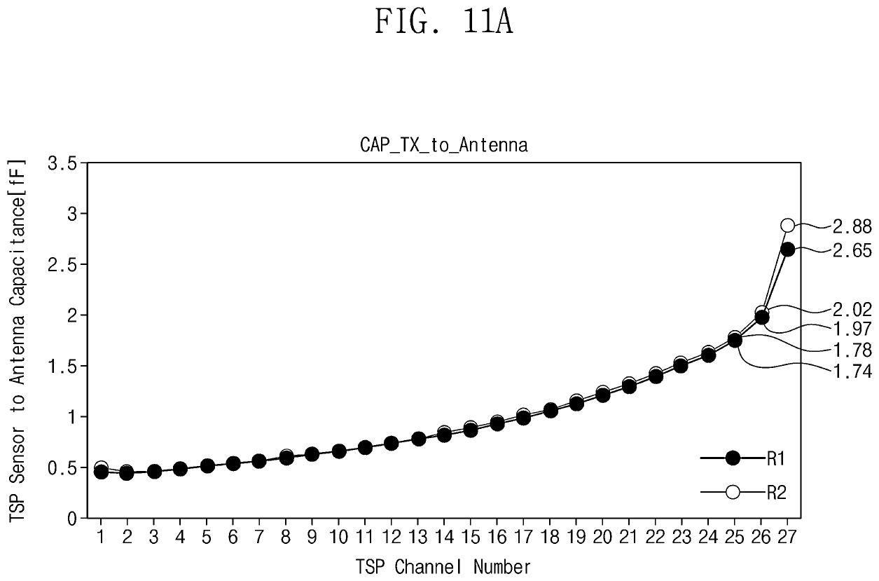

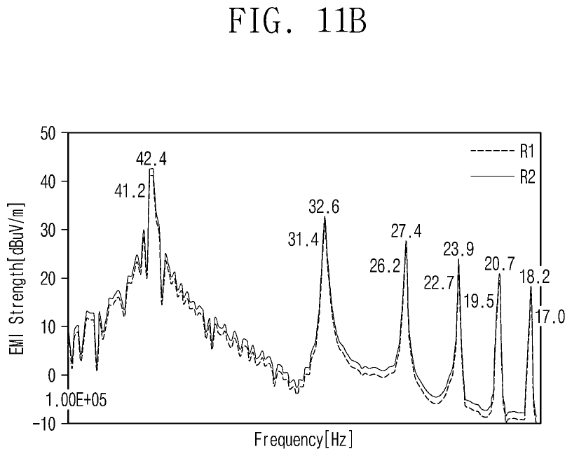

FIG. 11A is a graph illustrating an electric capacitance of a display device according to an embodiment of the present disclosure and a display device according to a comparative example.

In the present disclosure, embodiment 1 (R1) indicates the display device according to the embodiment of the present disclosure, and embodiment 2 (R2) indicates the display device according to the comparative example. Embodiment 2 (R2) does not include a component such as the ground pattern GL (refer to FIG. 7) of the present disclosure. In embodiment 1 (R1) and embodiment 2 (R2), a first sensing electrode TE1 is arranged in twenty-seven rows.

For the convenience of explanation, among the rows in which the first sensing electrodes TE1 are arranged, a row closest to a ground plane is referred to as a first row, and the rows are defined as being arranged sequentially in a direction away from the ground plane.

FIG. 11A shows a graph measuring a capacitance formed between a first sensing electrode TE1 (refer to FIG. 6A) and an antenna for measuring electromagnetic interference (hereinafter, referred to as an electromagnetic interference measuring antenna) when the first sensing electrode TE1 is connected with the electromagnetic interference measuring antenna by a conducting line.

Referring to FIG. 11A, since a large capacitance is formed between first electrode TE1 and the ground plane in the row of the first electrode TE1 (refer to FIG. 6A) near the ground plane, a relatively small capacitance is measured between the first electrode TE1 arranged in the row near the ground plane and the electromagnetic interference measuring antenna.

Referring to FIG. 11A, a capacitance of about 0.5 fF is measured in the first row of embodiment 1 (R1) and embodiment 2 (R2).

Referring to FIG. 11A, since a small capacitance is formed between the first electrode TE1 and the ground plane in the row of the first electrode TE1 (refer to FIG. 6A) far from the ground plane, a relatively large capacitance is formed between the first electrode TE1 arranged in the row far from the ground plane and the electromagnetic interference measuring antenna.

Referring to FIG. 11A, a capacitance of about 2.02 fF is measured in a twenty-sixth row of embodiment 2 (R2), and a capacitance of about 2.88 fF is measured in a twenty-seventh row of embodiment 2 (R2). Accordingly, a capacitance difference of about 0.86 fF exists between the twenty-sixth row and the twenty-seventh row of embodiment 2 (R2).

Referring to FIG. 11A, a capacitance of about 1.97 fF is measured in a twenty-sixth row of embodiment 1 (R1), and a capacitance of about 2.65 fF is measured in a twenty-seventh row of embodiment 1 (R1). Accordingly, a capacitance difference of about 0.68 fF exists between the twenty-sixth row and the twenty-seventh row of embodiment 1 (R1).

Therefore, when compared to embodiment 2 (R2), it is observed that the small capacitance is measured in the row of the first electrode TE1 far from the ground plane in embodiment 1 (R1), and the capacitance difference between the rows adjacent to each other is small. Accordingly, it is observed that embodiment 1 (R1) has the effect of reducing electromagnetic interference when compared to embodiment 2 (R2).

FIG. 11B is a graph illustrating an electromagnetic interference field strength of a display device according to an embodiment of the present disclosure and a display device according to a comparative example.

When measuring an EMI strength of embodiment 1 (R1) and embodiment 2 (R2), the display device of embodiment 1 (R1) and the display device of embodiment 2 (R2) were driven by a method of sensing an external input by a mutual capacitance type. For the convenience of explanation, FIG. 11B shows only values measured at peaks on the graph.

Referring to FIG. 11B, it is observed that embodiment 2 (R2) has an electric field strength of about 42.4, 32.6, 27.4, 23.9, 20.7, and 18.2 dBuV/m at the peaks, respectively, and embodiment 1 (R1) has an electric field strength of about 41.2, 31.4, 26.2, 22.7, 19.5, and 17.0 dBuV/m at the peaks, respectively. Accordingly, it is observed that embodiment 1 (R1) has a low electric field strength of about 1.2 dBuV/m with respect to the same scan rate. Consequently, it is observed that embodiment 1 (R1) has the effect of reducing electromagnetic interference when compared to embodiment 2 (R2).

Although the embodiments of the present disclosure have been described, it is understood that the present disclosure is not necessarily limited to these embodiments but various changes and modifications can be made by one of ordinary skill in the art within the spirit and scope of the present disclosure as hereinafter claimed. Therefore, the disclosed subject matter should not be limited to any single embodiment described herein.

What is claimed is:

1. A display device comprising:
a display panel comprising pixels, an encapsulation layer overlapping the pixels, and a dam; and
an input sensing panel disposed on the display panel, wherein the input sensing panel comprises an active area, a trace area adjacent to the active area, and a ground area spaced apart from the active area with the trace area interposed therebetween, sensing electrodes disposed in the active area, trace lines disposed in the trace area and connected to the sensing electrodes, and a ground pattern disposed in the trace area and the ground area,
wherein the dam overlaps the ground area, and the ground pattern overlaps the dam.

2. The display device of claim 1, wherein the encapsulation layer comprises a first encapsulation inorganic layer and an encapsulation organic layer disposed on the first encapsulation inorganic layer, and
wherein a first portion of the ground pattern overlaps the encapsulation organic layer, and a second portion of the ground pattern does not overlap the encapsulation organic layer.

3. The display device of claim 2, wherein the encapsulation layer further comprises a second encapsulation inorganic layer disposed on the encapsulation organic layer, the dam portion is covered by the second encapsulation inorganic layer, the second encapsulation inorganic layer is at least partially covered by the ground pattern, and the second encapsulation inorganic layer is at least partially exposed without being covered by the ground pattern in an area overlapping the dam portion.

4. The display device of claim 2, wherein the encapsulation layer further comprises a second encapsulation inorganic layer disposed on the encapsulation organic layer, and
wherein an end of the ground pattern is not aligned with an end of the second encapsulation inorganic layer when viewed in a plane.

5. The display device of claim 1, wherein the ground pattern comprises a first ground portion disposed in the trace area and a second ground portion disposed in the ground area.

6. The display device of claim 5, wherein the trace lines are not disposed between the first ground portion and the ground area, and the trace lines are disposed in an area closer to the active area than the first ground portion.

7. The display device of claim 1, wherein the input sensing panel comprises:
a first sensing insulating layer disposed directly on the display panel;
a first conductive layer disposed on the first sensing insulating layer;
a second sensing insulating layer disposed on the first sensing insulating layer and overlapping the first conductive layer;
a second conductive layer disposed on the second sensing insulating layer; and
a third sensing insulating layer disposed on the second sensing insulating layer and overlapping the second conductive layer,
wherein the trace lines correspond to portions of the first conductive layer or the second conductive layer.

8. The display device of claim 7, wherein the ground pattern comprises a same material as the first conductive layer or the second conductive layer.

9. The display device of claim 7, wherein the ground pattern comprises a first ground portion disposed in the trace area and a second ground portion disposed in the ground area,
wherein the first ground portion comprises a first lower ground included in the first conductive layer and a first upper ground included in the second conductive layer, and
wherein the second ground portion is an extension of the first lower ground or the first upper ground.

10. The display device of claim 7, wherein the ground pattern comprises a first ground portion disposed in the trace area and a second ground portion disposed in the ground area, and
wherein the first ground portion comprises a first upper ground included in the first conductive layer or a first lower ground included in the second conductive layer.

11. The display device of claim 7, wherein the ground pattern comprises a first ground portion disposed in the trace area and a second ground portion disposed in the ground area,
wherein the first ground portion comprises a bridge portion overlapping at least one of the trace lines, and
wherein the trace line overlapping the bridge portion is spaced apart from the bridge portion with the second sensing insulating layer interposed therebetween.

12. The display device of claim 1, wherein the sensing electrodes comprise first sensing electrodes and second sensing electrodes,
wherein each of the first sensing electrodes comprises first sensing patterns and first connection patterns extending from the first sensing patterns and formed integrally with the first sensing patterns,
wherein the second sensing electrodes comprise second sensing patterns and second connection patterns connecting the second sensing patterns adjacent to each other, and
wherein the first sensing patterns, the first connection patterns, and the second sensing patterns are disposed on a same layer, and the second connection patterns are disposed on a different layer from the second sensing patterns.

13. The display device of claim 1, wherein the trace area has a rectangular shape when viewed in a plane, and the ground pattern has an integral shape and overlaps at least one side of sides forming an outer portion of the trace area.

14. The display device of claim 13, wherein the ground pattern includes groove patterns recessed from an outer portion of the input sensing panel toward the active area.

15. The display device of claim 13, wherein the ground pattern includes openings spaced apart from each other, and
wherein each of the openings extends in a same direction in which a side forming the outer portion of the trace area adjacent to the openings extends.

16. The display device of claim 13, wherein the trace area has a rectangular shape when viewed in the plane and the ground pattern comprises sub-patterns which at least partially overlap the sides forming the outer portion of the trace area, and
wherein the sub-patterns are spaced apart from each other, and
wherein each of the sub-patterns has a rectangular shape extending along a same direction as a direction in which the overlapping side extends.

17. The display device of claim 1, wherein the trace area comprises a dummy area adjacent to the ground area, and the input sensing panel further comprises a dummy electrode,
wherein the dummy electrode is spaced apart from the trace line and disposed in the dummy area.

18. The display device of claim 1, further comprising:
a cover window disposed on the display panel and comprising a protrusion portion that does not overlap the display panel; and
a window electrode disposed between the display panel and the cover window,
wherein a light blocking area is in a lower surface of the cover window,
wherein the light blocking area overlaps the protrusion portion or the ground pattern and is coated with an ink, and
wherein the window electrode overlaps the light blocking area.

19. The display device of claim 18, further comprising a light blocking pattern disposed on a lower surface of the window electrode and a side surface of the window electrode.

20. The display device of claim 18, further comprising a conducting line, wherein a lower surface of the window electrode or a side surface of the window electrode comprises a connection area, the lower surface of the window electrode and the side surface of the window electrode except the connection area comprise a light blocking pattern disposed, the conducting line connects the window electrode and the ground pattern, one end of the conducting line is in contact with the window electrode in the connection area, and the other end of the conducting line is in contact with the ground pattern.
